(19) United States
(12) Patent Application Publication
(10) Pub. No.: US 2026/0020214 A1
(43) Pub. Date: Jan. 15, 2026

(54) TWO ACCESS DEVICE, ONE STORAGE NODE CELL FOR VERTICAL THREE-DIMENSIONAL MEMORY

(71) Applicant: Micron Technology, Inc., Boise, ID (US)

(72) Inventors: Kamal M. Karda, Boise, ID (US); Haitao Liu, Boise, ID (US); Litao Yang, Boise, ID (US)

(21) Appl. No.: 17/949,496

(22) Filed: Sep. 21, 2022

(51) Int. Cl. H10B 12/00; G11C 5/06; G11C 11/4091; H10B 51/20; H10B 51/30; H10B 53/20; H10B 53/30; H10D 30/67

(52) U.S. Cl. CPC H10B 12/00; G11C 5/063; H10B 12/01; H10B 51/20; H10B 51/30; H10B 53/20; H10B 53/30; H10D 30/6706; H10D 30/6733; H10D 30/6755; G11C 11/4091

(57) ABSTRACT

Systems, methods and apparatus are provided for a two access device, one storage node memory cell in a vertical three-dimensional memory. The memory cell has a first horizontally oriented access device having a first source/drain region and a second source/drain region separated by a first channel region. The first access device is operatively controlled by a first gate. The memory cell has a second horizontally oriented access device having a first source/drain region and a second source/drain region separated by a second channel region. The second access device is operatively controlled by a second gate. A shared storage node is coupled between the second source/drain regions of the first access device and the second access device.

### TECHNICAL FIELD

The present disclosure relates generally to memory devices, and more particularly, to a two access device, one storage node cell for vertical three-dimensional (3D) memory.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like. Memory devices can be utilized for a wide range of electronic applications.

### BRIEF DESCRIPTION OF THE DRAWINGS

FIGS. 1A-1B are schematic illustrations of portions of a vertical three-dimensional (3D) memory in accordance a number of embodiments of the present disclosure.

FIG. 2 is a perspective view illustrating a portion of a semiconductor device in accordance with a number of embodiments of the present disclosure.

FIGS. 3A-B are a perspective views illustrating a portion of a semiconductor device in accordance with a number of embodiments of the present disclosure.

FIG. 4 is a cross-sectional view for an example embodiment of a semiconductor device fabrication process for a two access device, one storage node (e.g., 2T1C) memory cell in accordance with a number of embodiments of the present disclosure.

FIGS. 5A-5B are views for an example embodiment of a semiconductor device fabrication process for a 2T1C memory cell in accordance with a number of embodiments of the present disclosure.

FIGS. 6A-6E are views for an example embodiment of a semiconductor device fabrication process for a 2T1C memory cell in accordance with a number of embodiments of the present disclosure.

FIGS. 7A-7G are views for an example embodiment of a semiconductor device fabrication process for a 2T1C memory cell in accordance with a number of embodiments of the present disclosure.

FIGS. 8A-8B are views illustrating portions of a semiconductor device in accordance with a number of embodiments of the present disclosure.

FIG. 9 is a block diagram of an apparatus in the form of a computing system including a memory device, in accordance with a number of embodiments of the present disclosure.

FIG. 10 is a schematic illustration of an operational embodiment of a two access device, one storage node memory cell, in accordance with a number of embodiments of the present disclosure.

### DETAILED DESCRIPTION

Embodiments of the present disclosure describe two access devices, e.g., transistors, one storage node, e.g., capacitor, cells for vertical three-dimensional (3D) memory. In one embodiment the access devices are transistors and a shared storage node is a capacitor forming a dynamic random access memory (DRAM) cell in a 3D memory. The two transistor, one capacitor (2T1C) cells share a storage node. The transistors are horizontally oriented and each share a horizontally oriented storage node located between the two (2) horizontally oriented transistors within a same plane, e.g., tier, of the vertical 3D memory. The horizontally oriented transistors are integrated with vertically oriented gates and integrated with horizontally oriented digit lines. This provides good retention and scalability, in part due to less horizontal area, e.g., footprint, for the memory cells, for vertical three-dimensional memories. Additionally the shared storage node provides for better retention relative to a same size one transistor, one capacitor (1T1C) memory cell and a better signal margin for improved sensing performance.

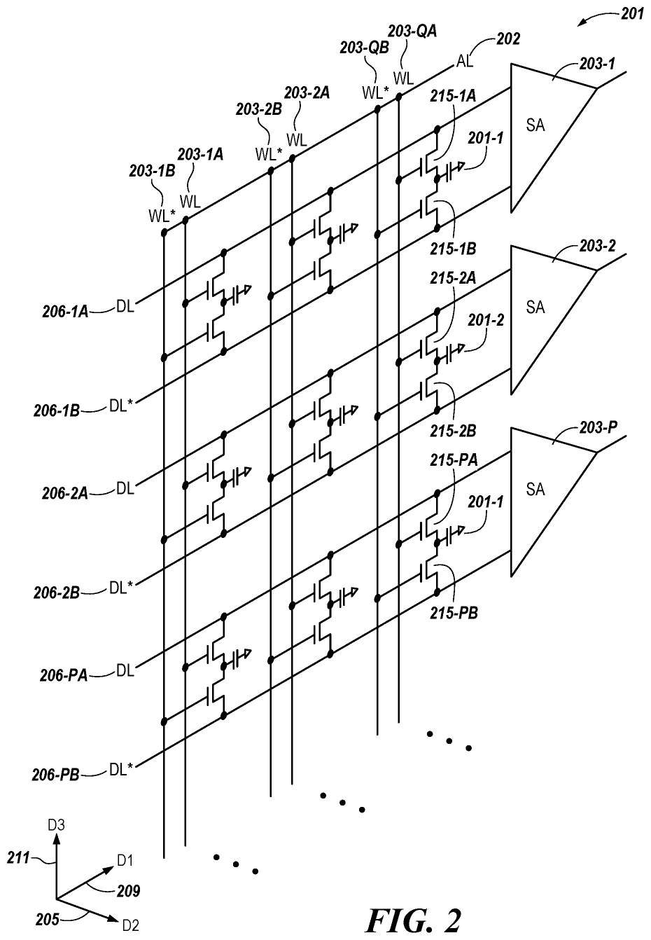

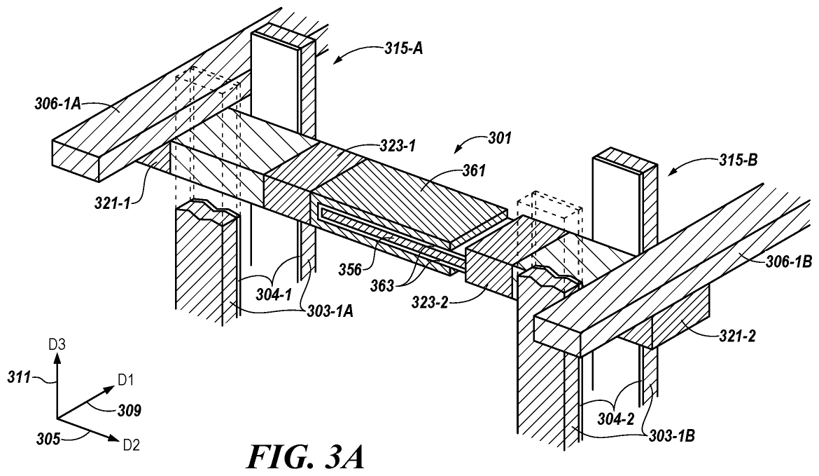

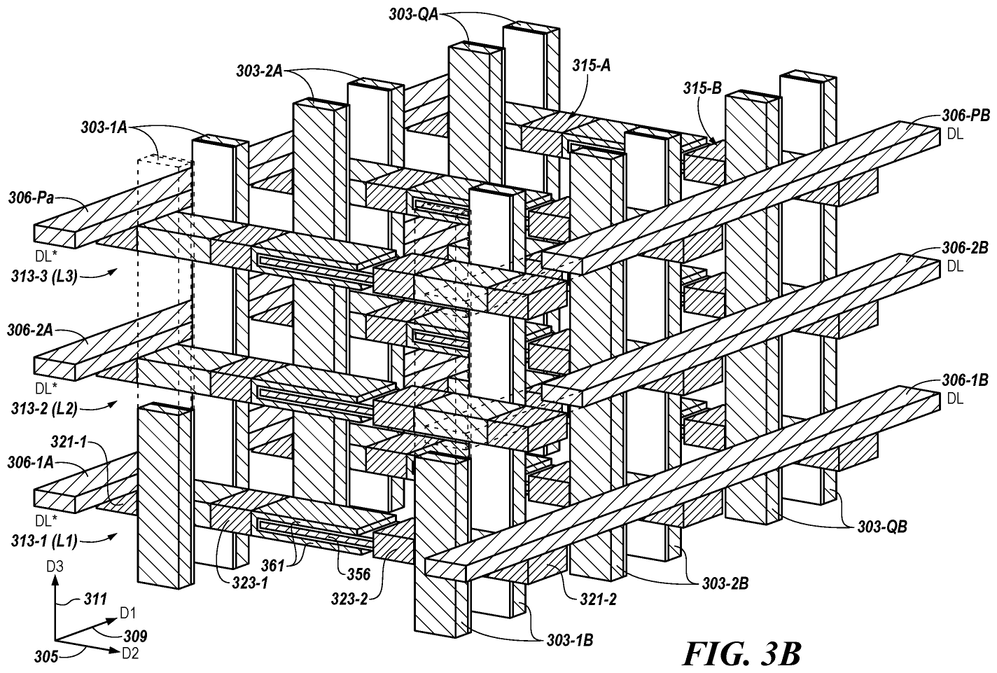

The figures herein follow a numbering convention in which the first digit or digits correspond to the figure number of the drawing and the remaining digits identify an element or component in the drawing. Similar elements or components between different figures may be identified by the use of similar digits. For example, reference numeral 223 may reference element “23” in FIG. 2, and a similar element may be referenced as 323 in FIG. 3. Multiple analogous elements within one figure may be referenced with a reference numeral followed by a hyphen and another numeral or a letter. For example, 207-1 may reference element 207-1 in FIGS. 2 and 207-2 may reference element 207-2, which may be analogous to element 207-1. Such analogous elements may be generally referenced without the hyphen and extra numeral or letter. For example, elements 207-1 and 207-2 or other analogous elements may be generally referenced as 207.

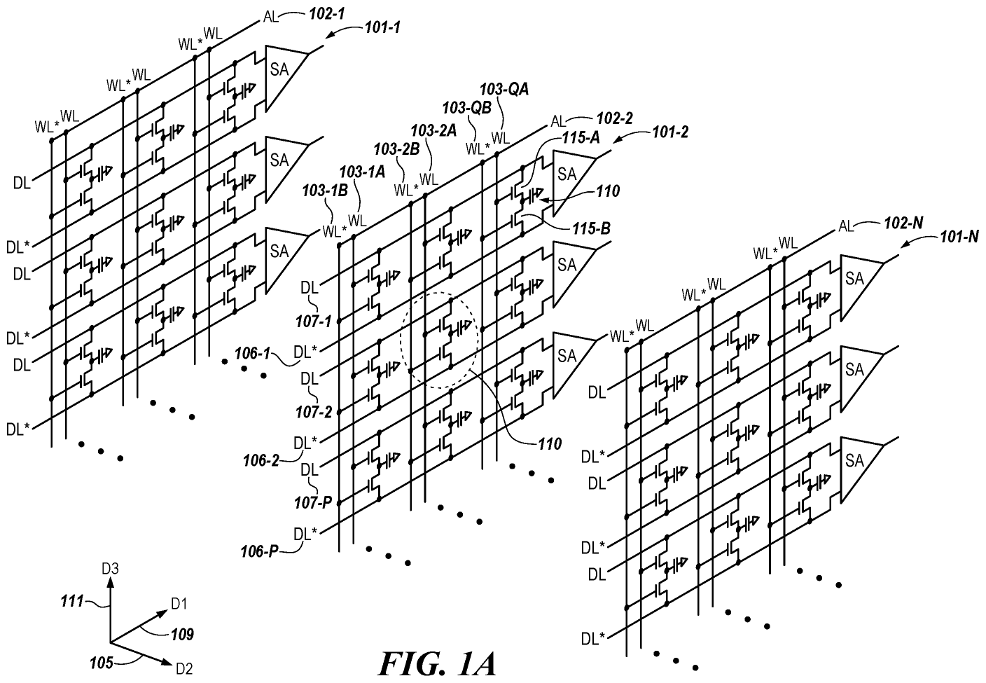

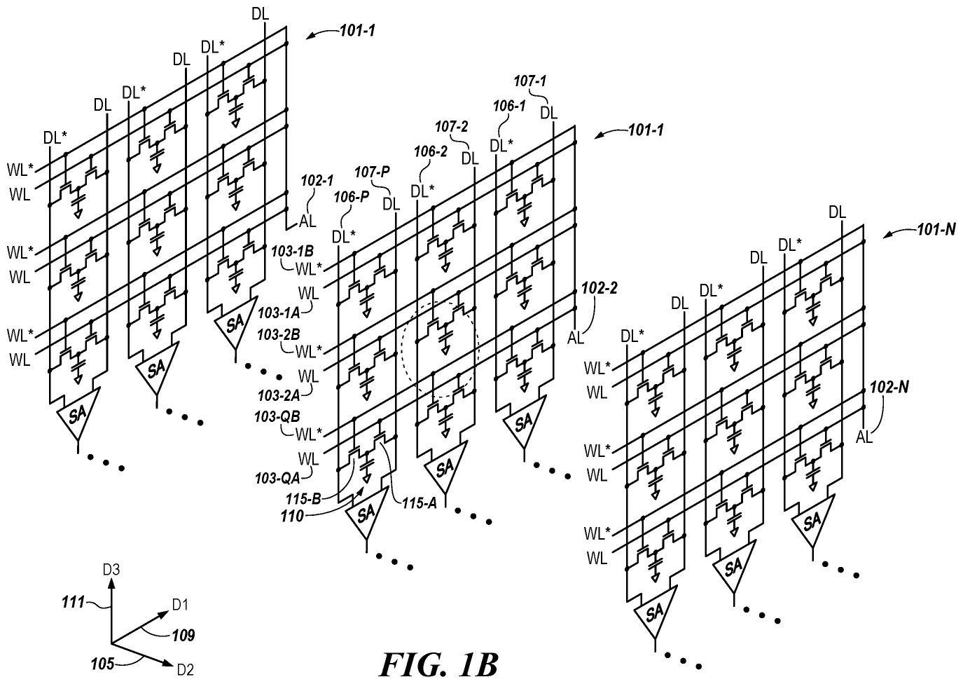

FIGS. 1A-1B are schematic illustrations of portions of a vertical 3D memory in accordance a number of embodiments of the present disclosure. FIG. 1A illustrates a circuit diagram showing a cell array of a 3D semiconductor memory device according to an embodiment of the present disclosure having vertically oriented gates (e.g., vertically oriented WLs 103-1A and 103-1B) oriented in a third direction (D3) 111 and horizontally oriented digit lines (e.g., Dl 106-1A and DL* 106-1B) oriented in a first direction (D1) 109. FIG. 1B illustrates a circuit diagram showing a cell array of a 3D semiconductor memory device according to an embodiment of the present disclosure having vertically oriented digit lines (e.g., Dl 106-1A and DL* 106-1B) oriented in the third direction (D3) 111 and horizontally oriented gates (e.g., horizontally oriented WLs 103-1A and 103-1B) oriented in the first direction (D1) 109. For ease of illustration, the description which follows will accord to the embodiment of FIG. 1A. However, embodiments are not so limited, and a rotation of the gates and digit lines of configuration and architecture shown in FIG. 1A by ninety (90) degrees relative to the third direction (D3) 111 will produce the configuration and architecture illustrated in FIG. 1B which is equally covered with the embodiments described herein.

FIG. 1A illustrates a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include vertically oriented gates 103-1A, 103-1B, 103-2A, 103-2B . . . , 103-QA, 103-QB (e.g., wordlines (WL/WLB)),. Each of the sub cell arrays may include horizontally oriented, complementary pairs of digit lines, 106-1A and 106-1B, 106-2A and 106-2B, . . . , 106-PA and 106-PB, associated with each two transistor, one capacitor memory cell, are respectively coupled a sense amplifier 103-1, 103-2, . . . , 103-P for sensing, extending in a first direction (D1) 109, while the vertically oriented gates 103-1A, 103-1B, 103-2A, 103-2B . . . , 103-QA, 103-QB (e.g., wordlines (WL/WLB)), are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the vertically oriented gates 103-1A, 103-1B, 103-2A, 103-2B . . . , 103-QA, 103-QB (e.g., wordlines (WL/WLB)), are extending in a vertical direction, e.g., third direction (D3) 111.

A memory cell (e.g., 110) may include two transistors 115-A and 115-B, and one shared capacitor 101, oriented in the second direction (D2) 105 located at intersections of the vertically oriented gates 103-1A, 103-1B, 103-2A, 103-2B . . . , 103-QA, 103-QB (e.g., wordlines (WL/WLB)) oriented in the third direction (D3) 111, and the complementary pairs of digit lines, 106-1A and 106-1B, 106-2A and 106-2B, . . . , 106-PA and 106-PB oriented in the first direction (D1) 109.

Memory cells may be written to, or read from, using the vertically oriented gates 103-1A, 103-1B, 103-2A, 103-2B . . . , 103-QA, 103-QB (e.g., wordlines (WL/WLB)), and the complementary pairs of digit lines, 106-1A and 106-1B, 106-2A and 106-2B, . . . , 106-PA and 106-PB (e.g., DL and DL*, or DL_bar). For example the vertically oriented gates 103-1A, 103-1B, 103-2A, 103-2B . . . , 103-QA, 103-QB (e.g., wordlines (WL/WLB)) can be activated, e.g., driven to a gate potential Vg of Vcc (power supply voltage (common collector)) pumped

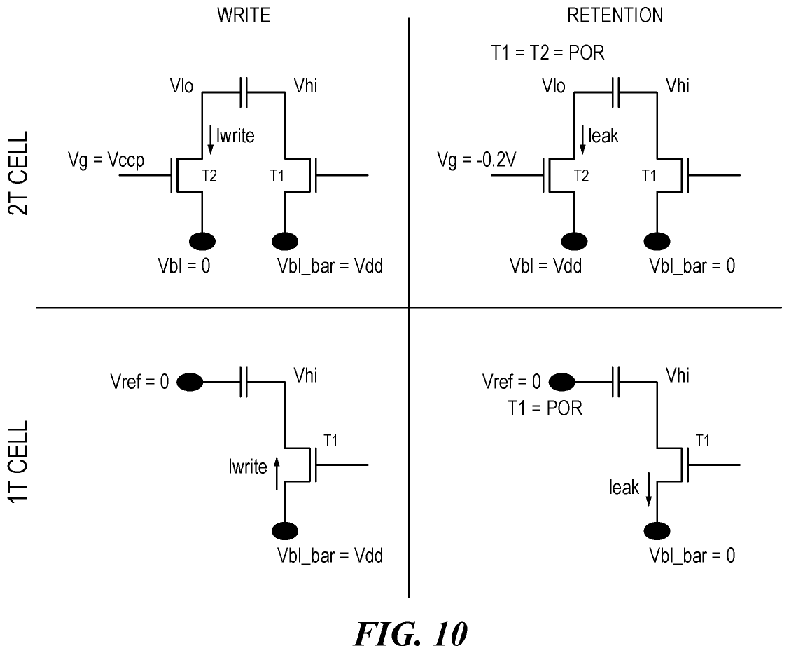

(Vccp), and the selected complement digit line (DL*) 106-1B, 106-2B, . . . , 106-PB can be driven to a voltage potential Vdd (power supply voltage (drain)), while digit line (DL) 106-1A, 106-2A, . . . , 106-PA is pulled to a ground potential (e.g., Vdl=0). This will result in a high voltage potential being placed on one electrode of the storage node capacitor, e.g., on the second node, while a low voltage potential will be formed on the other electrode of the storage node capacitor, e.g., on the first electrode. When the gate voltage potential (Vg) is removed, e.g., “off”, and the selected complement digit line (DL*) 106-1B, 106-2B, . . . , 106-PB is returned to ground potential (e.g., VDL* or Vdl_bar=0) and the digit line (DL) 106-1A, 106-2A, . . . , 106-PA is returned to voltage potential Vdd (e.g., VDL=Vdd) a charge (or potential difference of Vcc) will be held across the first electrode and the second electrode on the on the storage node capacitor with good stored charge retention. This is illustrated in FIG. 10 in which “Write and Retention” are contrasted according to this example embodiment operation for a two transistor, shared storage node (e.g., 2T1C) memory cell relative to previous one transistor, one capacitor (1T1C) memory cells. In a read operation the above “write” sequence may be reversed.

The complementary pairs of digit lines, 106-1A and 106-1B, 106-2A and 106-2B, . . . , 106-PA and 106-PB may conductively interconnect memory cells along horizontal rows of each sub cell array 101-, 101-2, . . . , 101-N, and the vertically oriented gates 103-1A, 103-1B, 103-2A, 103-2B . . . , 103-QA, 103-QB (e.g., wordlines (WL/WLB)), may conductively interconnect memory cells along vertical columns of each sub cell array 101-, 101-2, . . . , 101-N. Each memory cell may be uniquely addressed through a combination of vertically oriented gates 103-1A, 103-1B, 103-2A, 103-2B . . . , 103-QA, 103-QB (e.g., wordlines (WL/WLB)), and complementary pairs of digit lines, 106-1A and 106-1B, 106-2A and 106-2B, . . . , 106-PA and 106-PB.

A shared storage node 101 is coupled between second source/drain regions of the two transistors 115A and 115B of each two access device, one storage node memory cell. According to embodiments, a two access device, one storage node memory cell may reduce a horizontal area consumed for the vertical three-dimensional (3D) vertical memory to improve scaling and 3D vertical memory density. Additionally, the shared storage node may improve the sensing signal margin relative to a same capacitor size in a one transistor, one capacitor (1T1C) architecture. And, as an additional benefit, the arrangement of a two access device, one storage node memory cell relaxes the “current off” (“Ioff”) requirements, lessening current leakage in the access device “off”' state while realizing equivalent charge storage retention for thin film transistor (TFT) applications. Differential sensing is performed by the complementary pairs of digit lines, 106-1A and 106-1B, 106-2A and 106-2B, . . . , 106-PA and 106-PB resulting in improved sensing.

In one example, the two transistors 115-A and 115-B are horizontally oriented and each share a horizontally oriented storage node 101 located between the two (2) horizontally oriented transistors 115-A and 115-B within a same plane, e.g., tier, of the vertical 3D memory. The horizontally oriented transistors 115-A and 115-B are integrated with vertically oriented gates (303-1A and 303-1B shown in FIG. 3) and integrated with horizontally oriented, complementary digit lines, 106-A (DL) and 106-B (DL*), respectively coupled to sense amplifiers 103-1, . . . 103-P. In various embodiments, explained in more detail below in connection with FIG. 3, the storage nodes may have a first electrode coupled to the second source/drain region of a first access device 115-A and a second electrode coupled to a second source/drain region of a second access device 115-B. The first electrode and the second electrode may be separated by a dielectric material. In some embodiments the horizontally oriented, shared storage nodes 101 are capacitors. In some embodiments the horizontally oriented, shared storage nodes 101 are ferroelectric storage nodes.

FIG. 2 is a perspective view illustrating a portion of a semiconductor device in accordance with a number of embodiments of the present disclosure. FIG. 2 illustrates a perspective view showing a 3D semiconductor memory device (e.g., a portion of a sub cell array 101-2 shown in FIG. 1A) as a vertically oriented stack of memory cells in an array, according to some embodiments of the present disclosure.

As shown in FIG. 2, a substrate 200 may have formed thereon one of the plurality of sub cell arrays (e.g., 101-2 described in connection with FIG. 1A). For example, the substrate 200 may be or include a silicon substrate, a germanium substrate, or a silicon-germanium substrate, etc. Embodiments, however, are not limited to these examples.

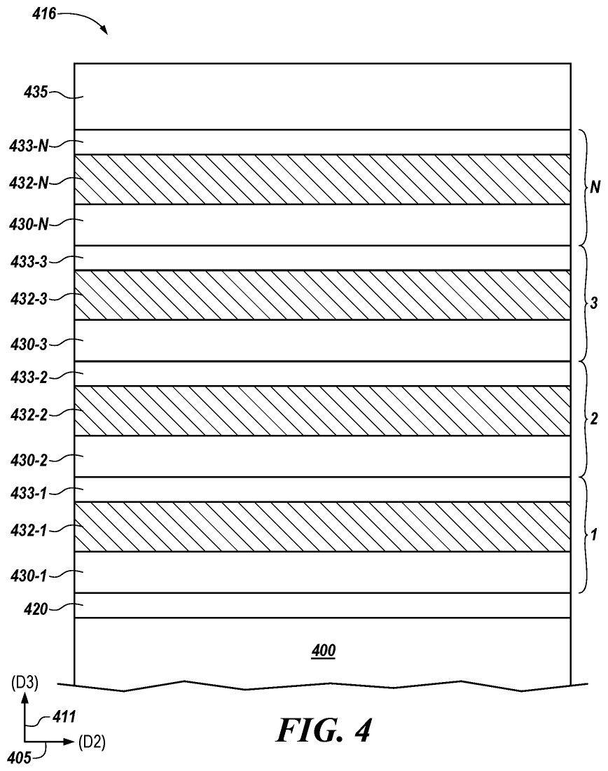

As shown in the example embodiment of FIG. 2, the substrate 200 may have fabricated thereon a vertically oriented stack of memory cells extending in a vertical direction, e.g., third direction (D3) 211. According to some embodiments the vertically oriented stack of memory cells may be fabricated such that the memory cells are formed on plurality of vertical levels (e.g., a first level 213-1 (L1), a second level 213-2 (L2), and a third level 213-3 (L3)). The repeating, vertical levels, L1, L2, and L3, may be arranged (e.g., “stacked”), the vertical direction (D3) 211, and may be separated from the substrate 200 by an insulator material 220. Each of the repeating, vertical levels, L1, L2, and L3 may include a number of components, e.g., regions, to the horizontally oriented transistors 215 A, 215-B, including vertically oriented gate pairs 203-1A/203-1-B, 203-2A/203-2B, . . . , 203-QA/203-QB that are connected together, e.g., “shorted” by control line 210, and horizontally oriented, complementary digit line pairs, e.g., digit lines (DLs) 206-1A, 206-2A, . . . , 206-PA and digit lines “bar” (DLs*) 206-1B, 206-2B, . . . , 206-PB, each coupled respectively to first source/drain regions of the two (2) access devices, e.g., transitors 215-A and 215-B. The number of components to the horizontally oriented transistors 215-A and 215-B may be formed in a plurality of iterations of vertically, repeating layers within each level (e.g., as described in more detail below in connection with FIG. 4) and may extend horizontally in the second direction (D2) 205, analogous to second direction (D2) 105 shown in FIG. 1A.

The horizontally oriented transistor 215-A can include a include a first source/drain region 221 and a second source/drain region 223 separated by a channel region 225. The second source/drain region 223 is coupled to a first electrode of a storage node, e.g., capacitor. The components of transistor 215-A extend laterally (e.g., horizontally) in the second direction (D2) 205.

The horizontally oriented transistor 215-B can include a include a first source/drain region 224 and the shared source/drain region 223 separated by a channel region 227. The components of transistor 215-B extend laterally (e.g., horizontally) in the second direction (D2) 205.

As shown in the example embodiment of FIG. 2, the two transistors 215-A and 215-B share a common storage node 201. The two transistors 215-A and 215-B are horizontally oriented and each share a horizontally oriented storage node 201 located between the two (2) horizontally oriented transistors 215-A and 215-B within a same plane, e.g., tier, of the vertical 3D memory. The horizontally oriented transistors 215-A and 215-B are integrated with vertically oriented gates (303-1A and 303-1B shown in FIG. 3) and integrated with horizontally oriented, complementary digit lines, 206-A (DL) and 206-B (DL*), respectively coupled to sense amplifiers 203-1, . . . , 203-P. The storage node comprising a first electrode 261 coupled to the second source/drain region 223-1 of the first access device 215-A and a second electrode 356 coupled to the second source/drain region 223-2 of the second access device 215-B. In some embodiments the horizontally oriented, shared storage nodes 201 are capacitors. In some embodiments the horizontally oriented, shared storage nodes 201 are ferroelectric storage nodes.

As shown in more detail in FIG. 3, in some embodiments the channel regions 325-A, 325-B may include silicon, germanium, silicon-germanium, and/or indium gallium zinc oxide (IGZO). In some embodiments, the source/drain regions, 321 and 323, can include an n-type dopant region formed in a p-type doped body to the transistor to form an n-type conductivity transistor. In some embodiments, the source/drain regions, 321 and 323, may include a p-type dopant formed within an n-type doped body to the transistor to form a p-type conductivity transistor. By way of example, and not by way of limitation, the n-type dopant may include Phosphorous (P) atoms and the p-type dopant may include atoms of Boron (B) formed in an oppositely doped body region of polysilicon semiconductor material. Embodiments, however, are not limited to these examples.

As shown in FIG. 2, the horizontally oriented, complementary pairs of digit lines, 206-1A and 206-1B, 206-2A and 206-2B, . . . , 206-PA and 206-PB, associated with each two transistor, one capacitor memory cell, are respectively coupled a sense amplifier 303-1, 303-2, . . . , 303-P for sensing. The horizontally oriented, complementary pairs of digit lines, 206-1A and 206-1B, 206-2A and 206-2B, . . . , 206-PA and 206-PB, extend in the first direction (D1) 209, analogous to the first direction (D1) 109 in FIG. 1A. The horizontally oriented, complementary pairs of digit lines, 206-1A and 206-1B, 206-2A and 206-2B, 206-PA and 206-PB, may be arranged, e.g., “stacked”, along the third direction (D3) 211. The horizontally oriented, complementary pairs of digit lines, 206-1A and 206-1B, 206-2A and 206-2B, . . . , 206-PA and 206-PB, may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1) 213-1, (L2) 213-2, and (L3) 213-P, the horizontally oriented, two transitor, one capacitor (2T1C) memory cells, e.g., 215-1A, 215-1B, and 301-1, may be spaced apart from one another horizontally in the first direction (D1) 209. However, the number of components to the transistors 215-A, e.g., first source/drain region 221, second source/drain region 223 separated by the channel region 225, and the horizontally oriented, complementary pairs of digit lines, 206-1A and 206-1B, 206-2A and 206-2B, . . . , 206-PA and 206-PB, may be formed within different vertical layers within each level. For example, the horizontally oriented, complementary pairs of digit lines, 206-1A and 206-1B, 206-2A and 206-2B, . . . , 206-PA and 206-PB, extending in the first direction (D1) 209, may be disposed on, and in electrical contact with, top surfaces of first source/drain regions 221 and orthogonal to the horizontally oriented transistors 215-A, which extend in laterally in the second direction (D2) 205. In some embodiments, the horizontally oriented, complementary pairs of digit lines, 206-1A and 206-1B, 206-2A and 206-2B, . . . , 206-PA and 206-PB, are formed in a higher vertical layer, farther from the substrate 200, within a level, e.g., within level (L1), than a layer in which the components, e.g., first source/drain region 221 and shared source/drain region 223 separated by the channel region 225, of the transistor 215-A are formed. In some embodiments, the horizontally oriented, complementary pairs of digit lines, 206-1A and 206-1B, 206-2A and 206-2B, . . . , 206-PA and 206-PB, may be connected to the top surfaces of the first source/drain regions 221 directly and/or through additional contacts including metal silicides.

As shown in the example embodiment of FIG. 2, vertically oriented gates 203-1A, 203-1B, 203-2A, 203-2B . . . , 203-QA, 203-QB (e.g., wordlines (WL/WLB)), opposing channel regions 225, extend in a vertical direction with respect to the substrate 200, e.g., in a third direction (D3) 211, and are coupled to, e.g., “shorted” to, a same control line 210. Further, as shown in FIG. 2, the vertically oriented gates 203-1A, 203-1B, 203-2A, 203-2B . . . , 203-QA, 203-QB (e.g., wordlines (WL/WLB)), in one sub cell array, e.g., sub cell array 101-2 in FIG. 1A, may be spaced apart from each other in the first direction (D1) 209. The vertically oriented gates 203-1A, 203-1B, 203-2A, 203-2B . . . , 203-QA, 203-QB (e.g., wordlines (WL/WLB)), may be provided, extending vertically relative to the substrate 200 in the third direction (D3) 211 between pairs of the laterally oriented transistors 215-A, 215-B extending laterally in the second direction (D2) 205, but adjacent to each other on a level, e.g., first level (L1), in the first direction (D1) 209. Each of the vertically oriented gates 203-1A, 203-1B, 203-2A, 203-2B . . . , 203-QA, 203-QB (e.g., wordlines (WL/WLB)), may vertically extend, in the third direction (D3), on sidewalls of respective ones of the plurality of horizontally oriented transistors 215-A, 215-B, which are vertically stacked.

For example, and as shown in more detail in FIG. 3, a first one of the vertically extending gates, e.g., 203-1A, may be adjacent a sidewall of a channel region 225 to one of the transistors 215-A, in the first level (L1) 213-1, a sidewall of a channel region 225 of another one of the transistors 215-A in the second level (L2) 213-2, and a sidewall of a channel region 225 a another one oriented of the transistors 215-A in the third level (L3) 213-P, etc. Embodiments are not limited to a particular number of levels.

The vertically extending vertically oriented gates 203-1A, 203-1B, 203-2A, 203-2B . . . , 203-QA, 203-QB (e.g., wordlines (WL/WLB)), may include a conductive material, such as, for example, one of a doped semiconductor material, a conductive metal nitride, metal, and/or a metal-semiconductor compound. The vertically oriented gates 203-1A, 203-1B, 203-2A, 203-2B . . . , 203-QA, 203-QB (e.g., wordlines (WL/WLB)), may respectively correspond to word lines WL and WLB connected to a same control line 310 extending in a first direction (D1) 209.

As shown in the example embodiment of FIG. 2, a conductive body contact 295 may be formed extending in the first direction (D1) 209 along an end surface of the transistors 215-A in each level (L1) 213-1, (L2) 213-2, and (L3) 213-P above the substrate 200. The body contact 295 may be connected to a body (e.g., body region) of the transistors 215-A, 215-B. The body contact 295 may include a conductive material such as, for example, one of a doped semiconductor material, a conductive metal nitride, metal, and/or a metal-semiconductor compound, among others.

Although not shown in FIG. 2, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIGS. 3A-3B are a perspective views illustrating a portion of a semiconductor device in accordance with a number of embodiments of the present disclosure. FIG. 3A illustrates a unit cell (e.g., two transistor, one capacitor (2T1C) memory cell 110 in FIG. 1A) of the vertically stacked array of memory cells (e.g., within a sub cell array 101-2 in FIG. 1A) according to some embodiments of the present disclosure. FIG. 3B illustrates an embodiment of the multiple unit cells, in multiple tiers, within a three-dimensional (3D) memory array.

The first source/drain regions 321-1 and 321-2 of the two transistors 315-A and 315-B, as well as the second source/drain regions 323-1 and 323-2, may be impurity doped regions.

As shown in FIGS. 3, the first source/drain regions 321-1 and 321-2 and the second source/drain region 323-1 and 323-2 may be separated by respective channel regions 325-1 and 325-2. The source/drain regions, 321 and 323, may be formed from an n-type or p-type dopant doped in the body region 326. Embodiments are not so limited.

For example, for an n-type conductivity transistor construction the body region and/or channel of the transistors 315 may be formed of a low doped (p−) p-type semiconductor material. In one embodiment, the body region and/or channels 325 respectively separating the source/drain regions, 321 and 323, may include a low doped, p-type (e.g., low dopant concentration (p−)) polysilicon material consisting of boron (B) atoms as an impurity dopant to the semiconductor material (e.g., polycrystalline silicon, among others). The source/drain regions and/or channel regions, 321, 323, and 325 may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In₂O₃), or indium tin oxide (In₂₋ₓSnₓO₃), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorous (P), boron (B), etc. Non-degenerate semiconductors, by contrast, contain moderate levels of doping, where the dopant atoms are well separated from each other in the semiconductor host lattice with negligible interaction.

For the n-type conductivity transistor construction, the source/drain regions 321 and 323 may include a high dopant concentration, n-type conductivity impurity (e.g., high dopant (n+) or (n++)) doped in the source/drain regions 321 and 323. In some embodiments, the high dopant, n-type conductivity source/drain regions 321 and 323 may include a high concentration of Phosphorus (P) atoms deposited therein. Embodiments, however, are not limited to this example. In other embodiments, the transistors 315 may be of a p-type conductivity construction in which case the impurity, e.g., dopant, conductivity types would be reversed.

Although not shown in the embodiment of FIG. 3, the source/drain regions 321 and 323 may occupy an upper portion in the body of the transistors 315. For example, the source/drain region 321 may have a bottom surface within the body of the transistor 315 which is located higher, vertically in the third direction (D3) 311, than a bottom surface of the body of the transistor 315. As such, the transistor 315 may have a body portion which is below the source/drain region 321, as well as source/drain region 323. The body portion may be in electrical contact with a body contact. Further, as shown FIG. 3, horizontally oriented, complementary pairs of digit lines, 306-1A and 306-1B (DL and DL*) may disposed on a top surface of the first source/drain regions 321 of the two transistors 315A and 315B and electrically coupled thereto.

As shown in the embodiment of FIG. 3, vertically oriented gates 303-1A and 303-1B of the two transistors 315A and 315B may be opposing channel regions 225-1 and 225-2, respectively, and vertically extending in the third direction (D3) 311. A gate dielectric material 304-1 and 304-2, respectively, may be interposed between the vertical gates 303-1A and 303-1B and the channel regions 325-1 and 325-2. The gate dielectric material 304-1 and 304-2 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 304-1 and 304-2 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 3, the two transistors 315-A and 315-B share a common storage node 301. The two transistors 315-A and 315-B are horizontally oriented, and each share a horizontally oriented storage node 301 located between the two (2) horizontally oriented transistors 315-A and 315-B within a same plane, e.g., tier, of the vertical 3D memory. The horizontally oriented transistors 315-A and 315-B are integrated with vertically oriented gates 303-1A and 303-1B and integrated with horizontally oriented, complementary digit lines, 306-1A (DL) and 306-1B (DL*), respectively coupled to sense amplifiers (203-1, . . . , 203-P shown in FIG. 2). The shared storage node comprises a first electrode 361 coupled to the second source/drain region 323-1 of the first access device 315-A and a second electrode 356 coupled to the second source/drain region 323-2 of the second access device 315-B. The first and the second electrodes, 361 and 356, are separated by a dielectric material 363, e.g., a “high-k dielectric material as described above, to form a floating, shared storage node. In some embodiments the horizontally oriented, shared storage nodes 301 are capacitors. In some embodiments the horizontally oriented, shared storage nodes 301 are ferroelectric storage nodes.

FIGS. 4-7 are cross-sectional views for an example embodiment of a semiconductor device fabrication process for a two access device, one storage node (e.g., 2T1C) memory cell in accordance with a number of embodiments of the present disclosure.

In the embodiment shown in FIG. 4, a semiconductor device fabrication process comprises depositing alternating layers of a first dielectric material, 430-1, 430-2, . . . , 430-N (collectively referred to as first dielectric material 430), a semiconductor material, 432-1, 432-2, . . . , 432-N (collectively referred to as semiconductor material 432), and a second dielectric material, 433-1, 433-2,., 433-N (collectively referred to as second dielectric 433), in repeating iterations to form a vertical stack 416 on a working surface of a substrate 400. The alternating materials in the repeating, vertical stack 416 may be separated from the substrate 400 by an insulator material 420. In one embodiment, the first dielectric material 430 can be deposited to have a thickness, e.g., vertical height in the third direction (D3), in a range of twenty (20) nanometers (nm) to sixty (60) nm. In one embodiment, the semiconductor material 432 can be deposited to have a thickness, e.g., vertical height, in a range of twenty (20) nm to one hundred (100) nm. In one embodiment, the second dielectric material 433 can be deposited to have a thickness, e.g., vertical height, in a range of ten (10) nm to thirty (30) nm. Embodiments, however, are not limited to these examples. As shown in FIG. 4, a vertical direction 411 is illustrated as a third direction (D3), e.g., z-direction in an x-y-z coordinate system.

In some embodiments, the first dielectric material, 430-1, 430-2, . . . , 430-N, may be an interlayer dielectric (ILD). By way of example, and not by way of limitation, the first dielectric material, 430-1, 430-2, . . . , 430-N, may comprise an oxide material, e.g., SiO₂. In another example the first dielectric material, 430-1, 430-2, . . . , 430-N, may comprise a silicon nitride (Si₃N₄) material (also referred to herein as “SiN”). In another example the first dielectric material, 430-1, 430-2, . . . , 430-N, may comprise a silicon oxy-carbide (SiOₓC_{y}) material. In another example the first dielectric material, 430-1, 430-2, . . . , 430-N, may include silicon oxy-nitride (SiOₓN_{y}) material (also referred to herein as “SiON”), and/or combinations thereof. Embodiments are not limited to these examples.

In some embodiments the semiconductor material, 432-1, 432-2, . . . , 432-N, may comprise a silicon (Si) material in a polycrystalline and/or amorphous state. The semiconductor material, 432-1, 432-2, . . . , 432-N, may be a low doped, p-type (p−) silicon material. The semiconductor material, 432-1, 432-2, . . . , 432-N, may be formed by gas phase doping boron atoms (B), as an impurity dopant, at a low concentration to form the low doped, p-type (p−) silicon material. The low doped, p-type (p−) silicon material may be a polysilicon material. Embodiments, however, are not limited to these examples.

In some embodiments, the second dielectric material, 433-1, 433-2, . . . , 433-N, may be an interlayer dielectric (ILD). By way of example, and not by way of limitation, the second dielectric material, 433-1, 433-2, . . . , 433-N, may comprise a nitride material. The nitride material may be a silicon nitride (Si₃N₄) material (also referred to herein as “SiN”). In another example the second dielectric material, 433-1, 433-2, . . . , 433-N, may comprise a silicon oxy-carbide (SiOC) material. In another example the second dielectric material, 433-1, 433-2, . . . , 433-N, may include silicon oxy-nitride (SiON), and/or combinations thereof.

Embodiments are not limited to these examples. However, according to embodiments, the second dielectric material, 433-1, 433-2, . . . , 433-N, is purposefully chosen to be different in material or composition than the first dielectric material, 430-1, 430-2, . . . , 430-N, such that a selective etch process may be performed on one of the first and second dielectric layers, selective to the other one of the first and the second dielectric layers, e.g., the second SiN dielectric material, 433-1, 433-2, . . . , 433-N, may be selectively etched relative to the semiconductor material, 432-1, 432-2, . . . , 432-N, and a first oxide dielectric material, 430-1, 430-2, . . . , 430-N.

The repeating iterations of alternating first dielectric material, 430-1, 430-2, . . . , 430-N layers, semiconductor material, 432-1, 432-2, . . . , 432-N layers, and second dielectric material, 433-1, 433-2, . . . , 433-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of a first dielectric material, a semiconductor material, and a second dielectric material, in repeating iterations to form the vertical stack 416.

The layers may occur in repeating iterations vertically. In the example of FIG. 4, three tiers, numbered 1, 2, and 3, of the repeating iterations 1-N are shown. For example, the stack 416 may include: a first dielectric material 430-1, a semiconductor material 432-1, a second dielectric material 433-1, a third dielectric material 430-2, a second semiconductor material 432-2, a fourth dielectric material 433-2, a fifth dielectric material 430-3, a third semiconductor material 432-3, and a sixth dielectric material 433-3. As such, a stack may include: a first oxide material 430-1, a first semiconductor material 432-1, a first nitride material 433-1, a second oxide material 430-2, a second semiconductor material 432-2, a second nitride material 433-2, a third oxide material 430-3, a third semiconductor material 432-3, and a third nitride material 433-3 in further repeating iterations. Embodiments, however, are not limited to this example and more or fewer repeating iterations may be included.

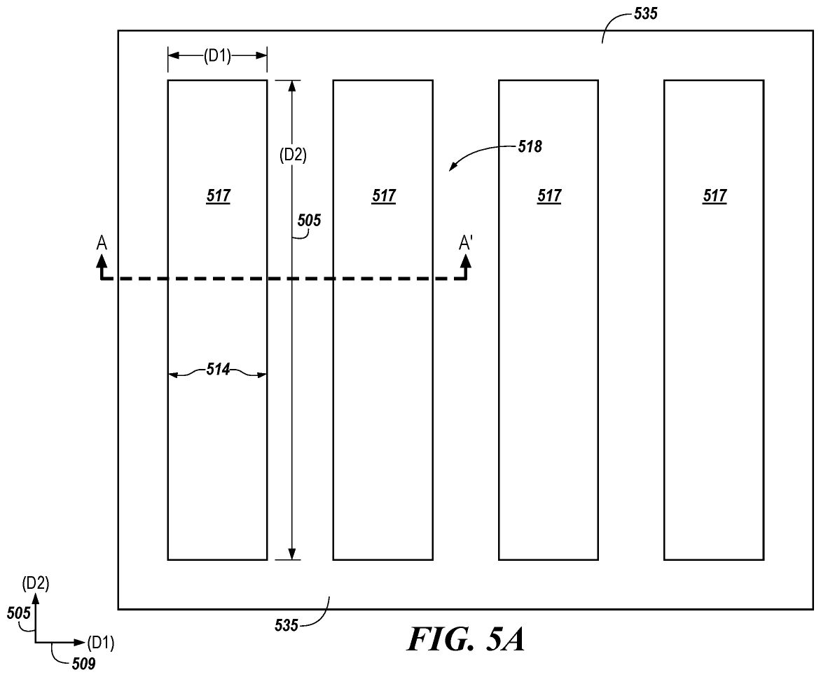

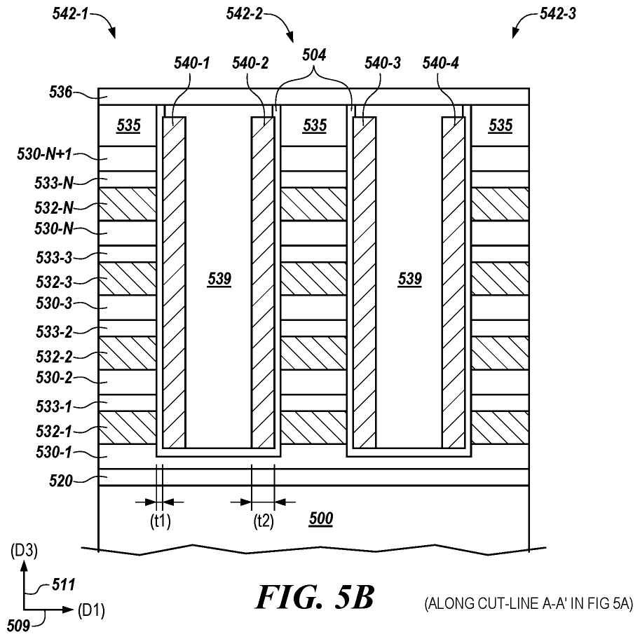

FIG. 5A is a view of a semiconductor device in fabrication, at one stage of a semiconductor device fabrication process in accordance with a number of embodiments of the present disclosure.

FIG. 5A illustrates a top-down view of a semiconductor device structure, at a particular point in time, in a semiconductor device fabrication process, according to one or more embodiments. In the example embodiment shown in the example of FIG. 5A, the semiconductor device fabrication process comprises using an etchant process to form a plurality of first vertical openings 517, having a first horizontal direction (D1) 509 and a second horizontal direction (D2) 505, through the vertical stack to the substrate. In one example, as shown in FIG. 5A, the plurality of first vertical openings 517 are extending predominantly in the second horizontal direction (D2) 505 and may form elongated vertical, pillar columns 518 with sidewalls 514 in the vertical stack. The plurality of first vertical openings 517 may be formed using photolithographic techniques to pattern a photolithographic mask 535, e.g., to form a hard mask (HM), on the vertical stack prior to etching the plurality of first vertical openings 517.

FIG. 5B is a cross-sectional view, taken along cut-line A-A′ in FIG. 5A. The cross-sectional view shown in FIG. 5B shows the repeating iterations of alternating layers of a first dielectric material, 530-1, 530-2, . . . , 530-N, a semiconductor material, 532-1, 532-2, . . . , 532-N, and a second dielectric material, 533-1, 533-2, . . . , 533-N, on a semiconductor substrate 500 and including an insulator 520. FIG. 5B illustrates that a conductive material, 540-1, 540-2, . . . 540-4, may be formed on a gate dielectric material 504 in the plurality of first vertical openings 517. By way of example and not by way of limitation, a gate dielectric material 504 may be conformally deposited in the plurality of first vertical openings 500 using a chemical vapor deposition (CVD) process, plasma enhanced CVD (PECVD), atomic layer deposition (ALD), or other suitable deposition process, to cover a bottom surface and the vertical sidewalls of the plurality of first vertical openings. The gate dielectric 504 may be deposited to a particular thickness (t1) as suited to a particular design rule (e.g., a gate dielectric thickness of approximately 10 nanometers (nm), among other values). Embodiments, however, are not limited to this example. By way of example, and not by way of limitation, the gate dielectric 504 may comprise a silicon dioxide (SiO₂) material, aluminum oxide (Al₂O₃) material, high dielectric constant (k), e.g., high-k, dielectric material, and/or combinations thereof.

As shown in FIG. 5B, the conductive material, 540-1, 540-2, . . . , 540-4, may be conformally deposited in the plurality of first vertical openings 517 on a surface of the gate dielectric material 504. By way of example, and not by way of limitation, the conductive material, 540-1, 540-2, . . . , 540-4, may be conformally deposited in the plurality of first vertical openings 517 on a surface of the gate dielectric material 504 using a chemical vapor deposition process (CVD), plasma enhanced CVD (PECVD), atomic layer deposition (ALD), or other suitable deposition process, to cover a bottom surface and the vertical sidewalls of the plurality of first vertical openings over the gate dielectric 504. The conductive material, 540-1, 540-2, . . . , 540-4, may be conformally deposited to a particular thickness (t2) to form vertically oriented access lines (e.g., a number of which may correspond to 103-1A and 103-1B, 103-2A and 103-2B, . . . , 103-QA and 103-QB shown in FIG. 1A) and can be suited to a particular design rule. For example, the conductive material, 540-1, 540-2, . . . , 540-4 may be conformally deposited to a thickness of approximately 20 nanometers (nm), among other values. Embodiments, however, are not limited to this example. By way of example, and not by way of limitation, the conductive material, 540-1, 540-2, . . . , 540-4, may comprise one or more of a doped semiconductor (e.g., doped silicon, doped germanium, etc.), a conductive metal nitride (e.g., titanium nitride, tantalum nitride, etc.), a metal (e.g., tungsten (W), titanium (Ti), tantalum (Ta), ruthenium (Ru), cobalt (Co), molybdenum (Mo), etc.), and/or a metal-semiconductor compound (e.g., tungsten silicide, cobalt silicide, titanium silicide, etc,) and/or some other combination thereof.

As shown in FIG. 5B, the conductive material, 540-1, 540-2, . . . 540-4, may be recessed back to remain only along the vertical sidewalls of the elongated vertical, pillar columns, which are shown as 542-1, 542-2, and 542-3 in FIG. 5B. The plurality of separate, vertical access lines formed from the conductive material, 540-1, 540-2, . . . , 540-4, may be recessed back by using a suitable selective, anisotropic etch process remove the conductive material, 540-1, 540-2, . . . , 540-4, from a bottom surface of the first vertical openings (e.g., 517 in FIG. 5A) exposing the gate dielectric 504 on the bottom surface to form separate, vertical access lines, 540-1, 540-2, . . . , 540-4. As shown in FIG. 5B, a dielectric material 539, such as an oxide or other suitable spin on dielectric (SOD), may then be deposited in the first vertical openings 517, using a process such as CVD, to fill the first vertical openings 517. The dielectric may be planarized to a top surface of the hard mask 535 of the vertical semiconductor stack, using chemical mechanical planarization (CMP) or other suitable semiconductor fabrication technique. A subsequent photolithographic material 536 (e.g., hard mask) may be deposited using CVD and planarized using CMP to cover and close the first vertical openings 517 over the separate, vertical access lines, 540-1, 540-2, . . . , 540-4. Similar semiconductor process techniques may be used at other points of the semiconductor fabrication device process herein.

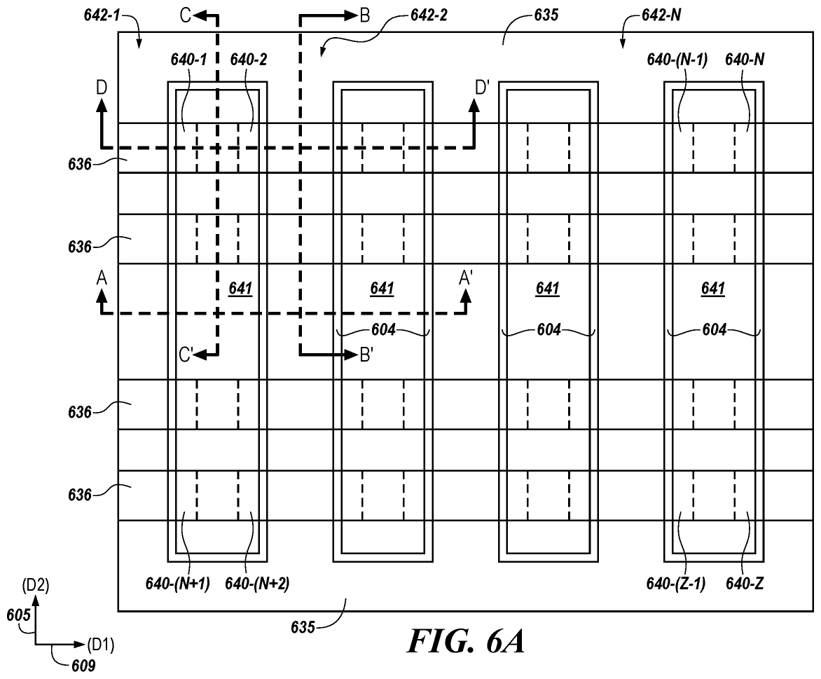

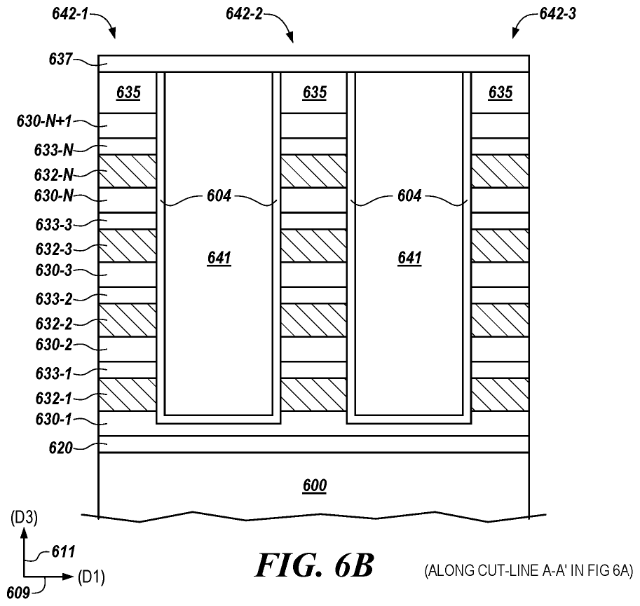

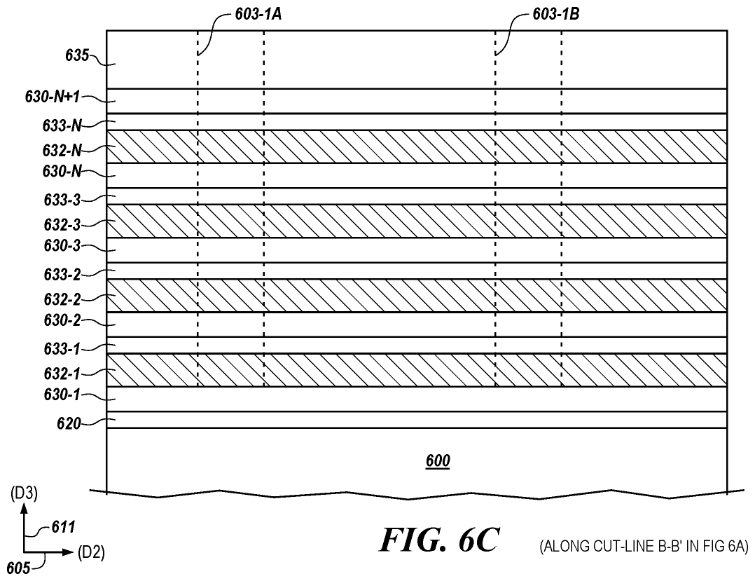

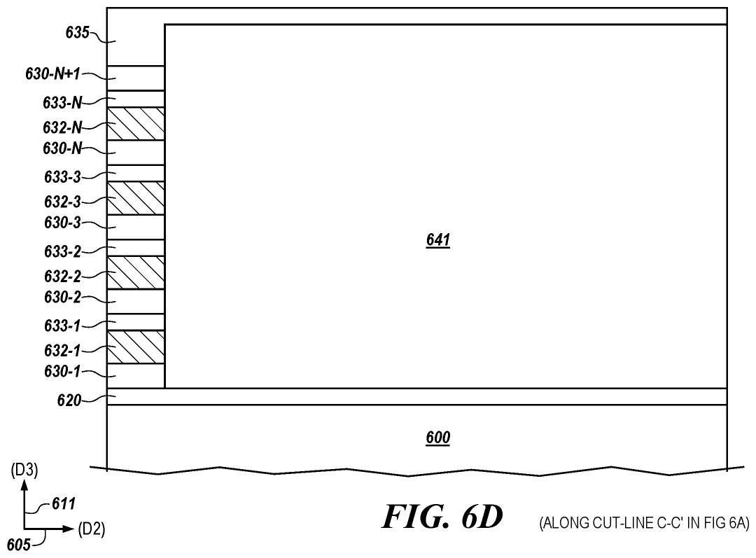

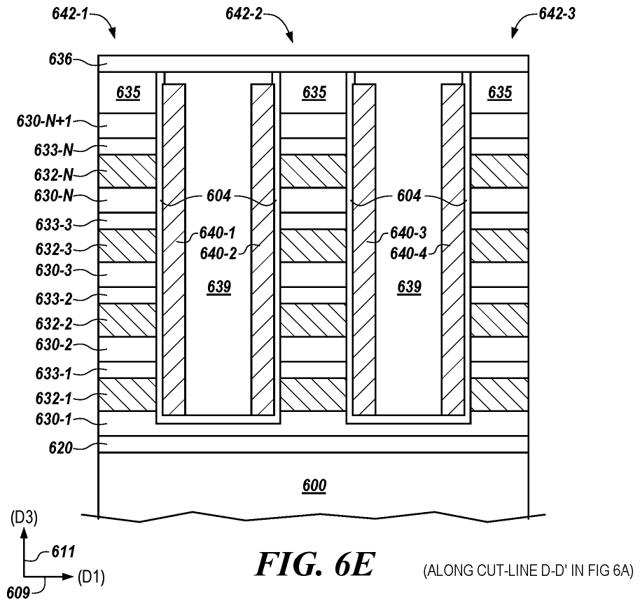

FIG. 6A is a view of a semiconductor device in fabrication, at one stage of a semiconductor device fabrication process in accordance with a number of embodiments of the present disclosure. FIG. 6A illustrates a top down view of a semiconductor structure, at a particular point in time, in a semiconductor device fabrication process, according to one or more embodiments. In the example embodiment of FIG. 6A, the fabrication comprises using a photolithographic process to pattern the photolithographic mask 636, 536 in FIG. 5B. FIG. 6A illustrates using a selective, isotropic etchant process remove portions of the exposed conductive material, 640-1, 640-2, . . . , 640-N, 640-(N+1), . . . , 640-(Z−1), and 640-Z, to separate and individually form the plurality of separate, vertical access lines, 640-1, 640-2, . . . , 640-N, 640-(N+1), . . . , 640-(Z−1), and 640-Z E (e.g., a number of which may correspond to 103-1A and 103-1B, 103-2A and 103-2B, . . . , 103-QA and 103-QB shown in FIG. 1A). Hence the plurality of separate, vertical access lines, 640-1, 640-2, . . . , 640-N, 640-(N+1), . . . , 640-(Z−1), and 640-Z, are shown along the sidewalls of the elongated vertical, pillar columns 642-1, 642-2, . . . 642-N (e.g., along sidewalls of the elongated vertical, pillar columns 542-1, 542-2, and 542-3 in the cross-sectional view of FIG. 5B).

As shown in the example of FIG. 6A, the exposed conductive material, 640-1, 640-2, . . . , 640-N, 640-(N+1), . . . , 640-(Z−1), and 640-Z, may be removed back to the gate dielectric material 604 in the first vertical openings (e.g., 517 in FIG. 5A) using a suitable selective, isotropic etch process. As shown in FIG. 6A, a subsequent dielectric material 641, such as an oxide or other suitable spin on dielectric (SOD), may then be deposited to fill the remaining openings from where the exposed conductive material, 640-1, 640-2, . . . , 640-N, 640-(N+1), . . . , 640-(Z−1), and 640-Z, was removed using a process such as CVD, or other suitable technique. The dielectric material 641 may be planarized to a top surface of the previous hard mask 635 of the vertical semiconductor stack (e.g., vertical stack 416 as shown in FIG. 4) using a process such as CMP, or other suitable technique. In some embodiments, a subsequent photolithographic material (e.g., hard mask 637 shown in FIG. 6B) may, may be deposited using CVD and planarized using CMP to cover and close the plurality of separate, vertical access lines, 640-1, 640-2, 640-N, 640-(N+1), . . . , 640-(Z−1), and 640-Z, (e.g., a number of which may correspond to 103-1A and 103-1B, 103-2A and 103-2B, . . . , 103-QA and 103-QB shown in FIG. 1A) over a working surface of the vertical semiconductor stack, leaving the plurality of separate, vertical access lines, 640-1, 640-2, . . . , 640-N, 640-(N+1), . . . , 640-(Z−1), and 640-Z, protected along the sidewalls of the elongated vertical, pillar columns. Embodiments, however, are not limited to these process examples.

FIG. 6B illustrates a cross sectional view, taken along cut-line A-A′ in FIG. 6A. FIG. 6B shows another view of the semiconductor structure at a particular point in one example of semiconductor device fabrication process. The cross sectional view shown in FIG. 6B is away from the plurality of separate, vertical access lines, 640-1, 640-2, . . . , 640-N, 640-(N+1), . . . , 640-(Z−1) (e.g., a number of which may correspond to 103-1A and 103-1B, 103-2A and 103-2B,., 103-QA and 103-QB shown in FIG. 1A), and shows the repeating iterations of alternating layers of a first dielectric material, 630-1, 630-2, . . . , 630-N, a semiconductor material, 632-1, 632-2, . . . , 632-N, and a second dielectric material, 633-1, 633-2, . . . , 633-N on a semiconductor substrate 600 including insulator 620. As shown in FIG. 6B, a vertical direction 611 is illustrated as a third direction (D3), e.g., z-direction in an x-y-z coordinate system, analogous to the third direction (D3) 111, among first, second and third directions, shown in FIGS. 1-3. The plane of the drawing sheet, extending right and left, is in a first direction (D1) 609. In the embodiment of FIG. 6B, the dielectric material 641 is shown filling the vertical openings on the residual gate dielectric 604 deposition. The hard mask 637 caps the illustrated structure.

FIG. 6C illustrates a cross sectional view, taken along cut-line B-B′ in FIG. 6A. FIG. 6C shows another view of the semiconductor structure at a particular point in one example of semiconductor device fabrication process. The cross sectional view shown in FIG. 6C is illustrated extending in the second direction (D2) 605 along an axis of the repeating iterations of alternating layers of a first dielectric material, 630-1, 630-2, . . . , 630-N, a semiconductor material, 632-1, 632-2, . . . , 632-N, and a second dielectric material, 633-1, 633-2, . . . , 633-N, along and in which the horizontally oriented transistors (e.g., 115-A and 115-B shown in FIG. 1A) can be formed within the layers of semiconductor material, 632-1, 632-2, . . . , 632-N. In FIG. 6C, a pair of vertical access lines 603-1A, 603-1B (e.g., corresponding to conductive materials 640, previously mentioned) is illustrated by a dashed line indicating a location set in from the plane and orientation of the drawing sheet.

FIG. 6D illustrates a cross sectional view, taken along cut-line C-C′ in FIG. 6A. FIG. 6D shows another view of the semiconductor structure at a particular point in one example of semiconductor device fabrication process. The cross sectional view shown in FIG. 6D is illustrated extending in the second direction (D2) 605 along an axis of the repeating iterations of alternating layers of a first dielectric material, 630-1, 630-2, . . . , 630-N, a semiconductor material, 632-1, 632-2, . . . , 632-N, and a second dielectric material, 633-1, 633-2, . . . , 633-N, outside of a region in which the horizontally oriented transistors and horizontally oriented storage nodes, e.g., capacitor cells, will be formed within the layers of semiconductor material, 632-1, 632-2, . . . , 632-N. In FIG. 6D, the dielectric material 641 is shown filling the vertical openings from another perspective. At the left end of the drawing sheet is shown the repeating iterations of alternating layers of a first dielectric material, 630-1, 630-2, . . . , 630-N, a semiconductor material, 632-1, 632-2, . . . , 632-N, and a second dielectric material, 633-1, 633-2, . . . , 633-N, at which location a horizontally oriented digit line (e.g., digit lines 107-1, 107-2, . . . , 107-P shown in FIG. 1A) can be integrated to form electrical contact with the source/drain regions of a transistor (e.g., transistor 115-A shown in FIG. 1A) or digit line conductive contact material, described in more detail below.

FIG. 6E illustrates a cross sectional view, taken along cut-line D-D′ in FIG. 6A. FIG. 6E shows another view of the semiconductor structure at a particular point in one example of semiconductor device fabrication process. The cross sectional view shown in FIG. 6E is illustrated, right to left in the plane of the drawing sheet, extending in the first direction (D1) 609 along an axis of the repeating iterations of alternating layers of a first dielectric material, 630-1, 630-2, . . . , 630-N, a semiconductor material, 632-1, 632-2, . . . , 632-N, and a second dielectric material, 633-1, 633-2, . . . , 633-N, intersecting across the plurality of separate, vertical access lines, 640-1, 640-2, . . . , 640-N, 640-(N+1), . . . , 640-(Z−1), and intersecting regions of the semiconductor material, 632-1, 632-2, . . . , 632-N, in which a channel region may be formed, separated from the plurality of separate, vertical access lines, 640-1, 640-2, . . . , 640-N, 640-(N+1), . . . , 640-(Z−1) (e.g., a number of which may correspond to 103-1A and 103-1B, 103-2A and 103-2B, . . . , 103-QA and 103-QB shown in FIG. 1A), by the gate dielectric 604. In FIG. 6E, the first dielectric fill material 639 is shown separating the space between neighboring horizontally oriented transistors, which may be formed extending into and out from the plane of the drawing sheet and can be spaced along a first direction (D1) 609 and stacked vertically in arrays extending in the third direction (D3) 611 in the 3D memory.

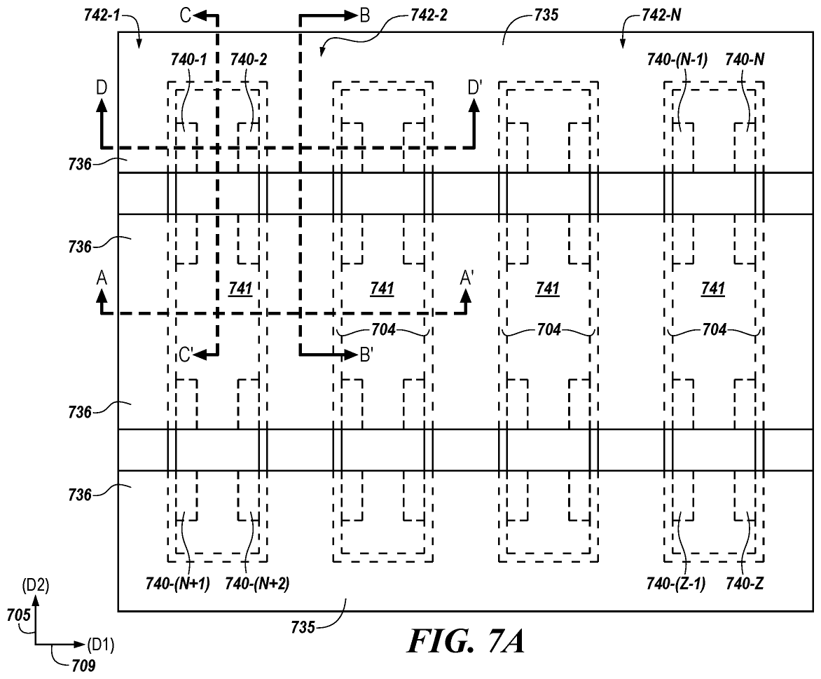

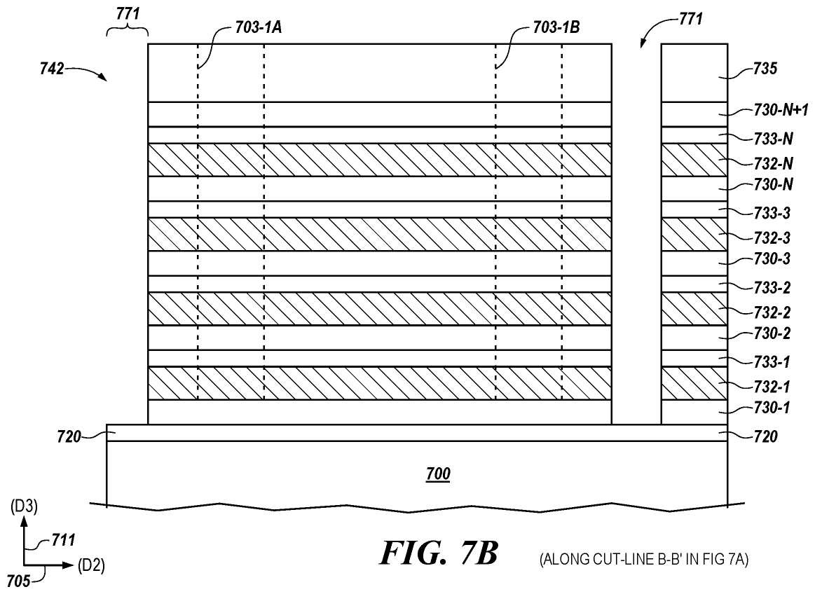

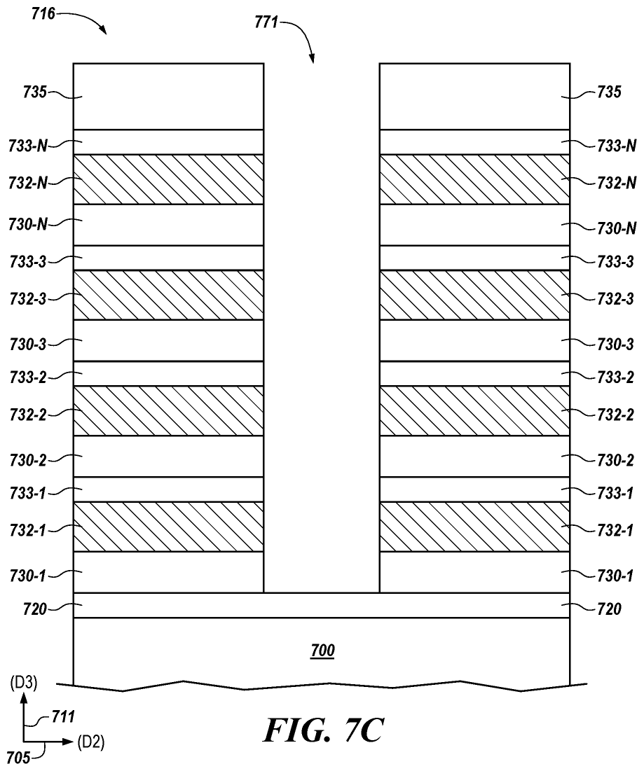

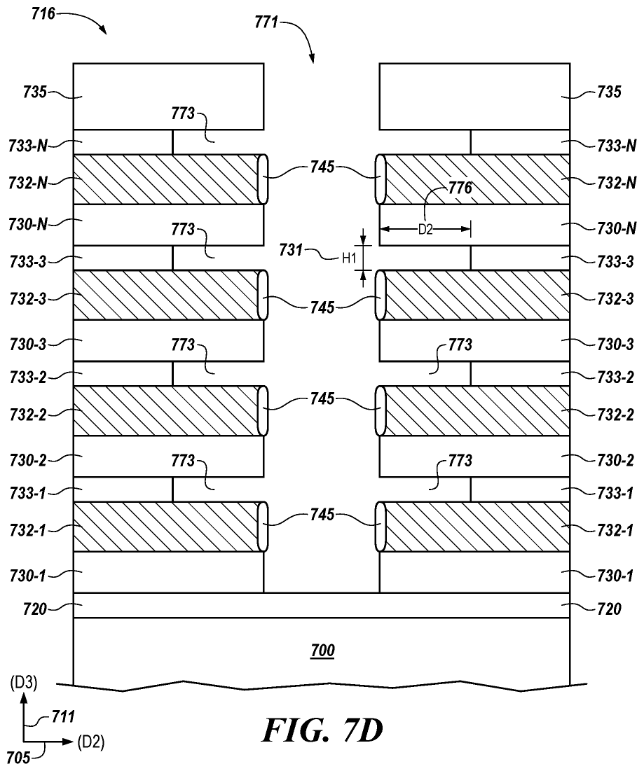

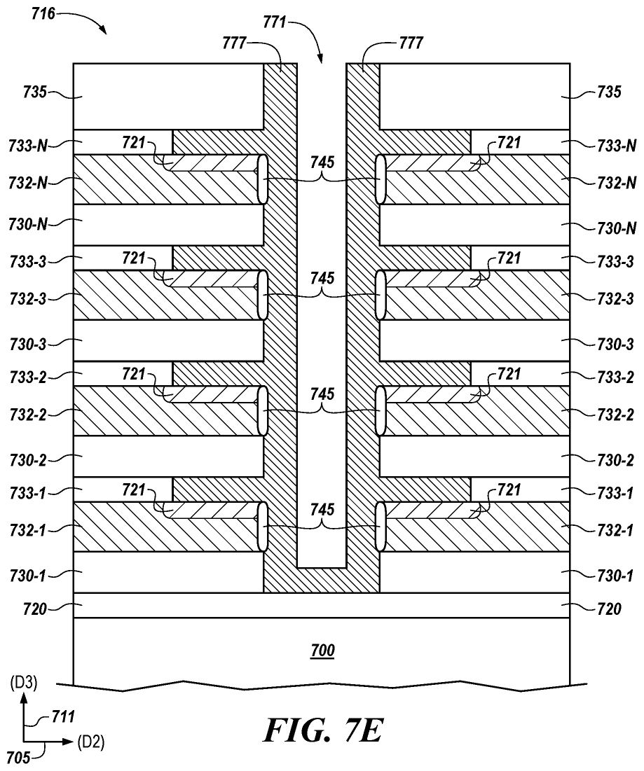

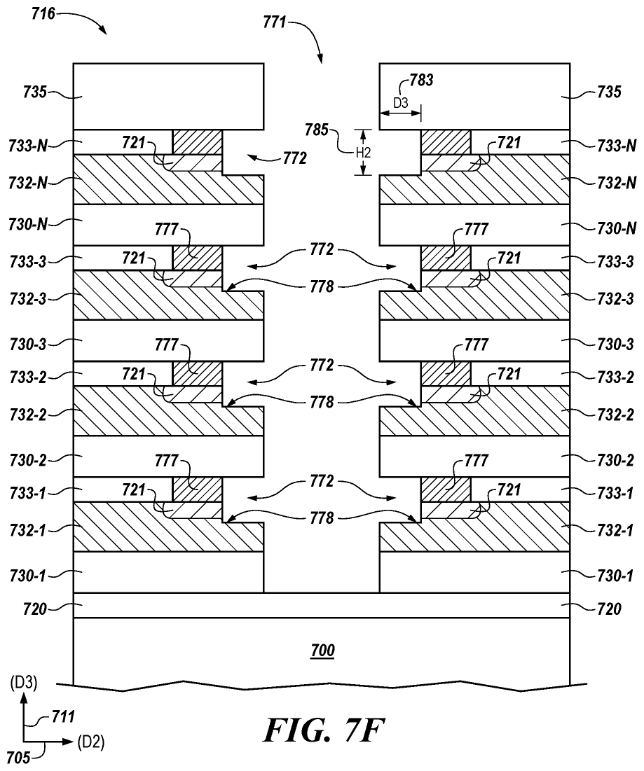

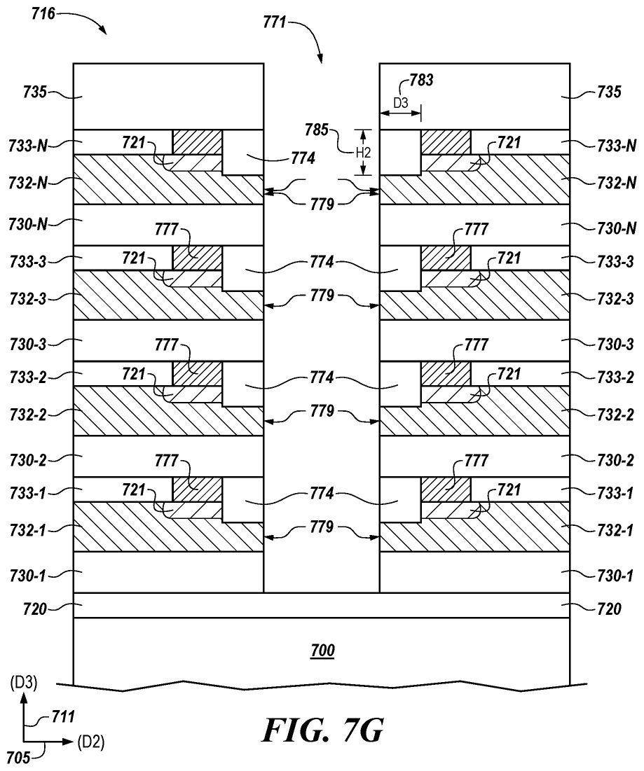

FIG. 7A illustrates a top down view of a semiconductor structure, at a particular point in time, in a semiconductor device fabrication process, according to one or more embodiments. In the example embodiment of FIG. 7A, the fabrication comprises using a photolithographic process to pattern the photolithographic mask 736, 536 in FIG. 5B. FIG. 7A illustrates using a selective, isotropic etchant process remove portions of the dielectric material 741 along sidewalls of the elongated vertical, pillar columns (e.g., 542-1, 542-2, and 542-3 in the cross-sectional view of FIG. 5B).

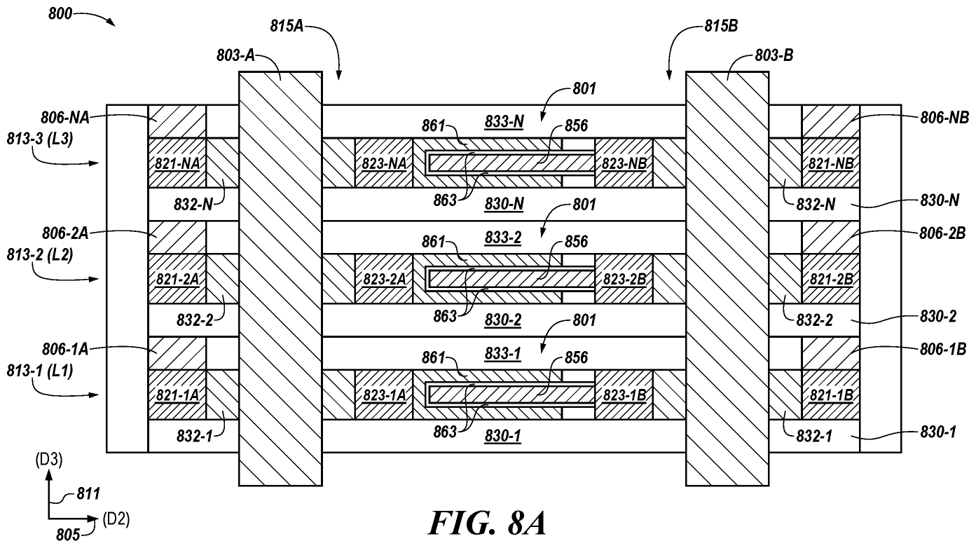

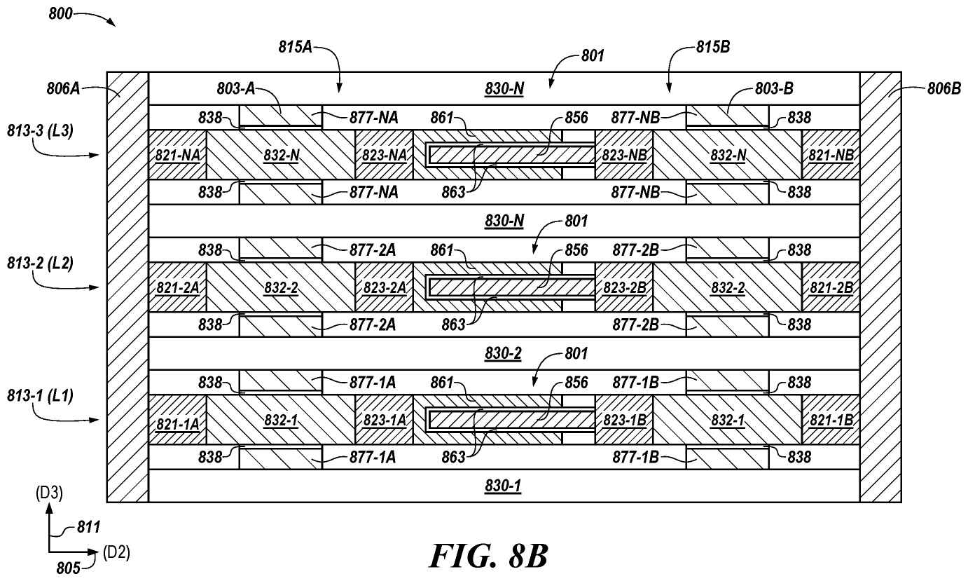

In the part, in the example embodiment of FIG. 7A, the exposed dielectric material 741 may be removed back to the gate dielectric material 604 in the first vertical openings (e.g., 517 in FIG. 5A) using a suitable selective, isotropic etch process. A subsequent selective etch process may then be used to remove the semiconductor material 732 in regions between access devices in which to form storage nodes with floating electrodes coupled to respective second source/drain regions of the first and second access devices described herein and shown in more detail in FIG. 8.

FIG. 7B illustrates a cross sectional view, taken along cut-line B-B′ in FIG. 7A. FIG. 7B shows another view of the semiconductor structure at a particular point in one example of semiconductor device fabrication process. The cross sectional view shown in FIG. 7B is illustrated extending in the second direction (D2) 705 along an axis of the repeating iterations of alternating layers of a first dielectric material, 730-1, 730-2, . . . , 730-N, a semiconductor material, 732-1, 732-2, . . . , 732-N, and a second dielectric material, 733-1, 733-2, . . . , 733-N, along and in which the horizontally oriented transistors (e.g., 115-A and 115-B shown in FIG. 1A) can be formed within the layers of semiconductor material, 732-1, 732-2, . . . , 732-N. In FIG. 7B, a pair of vertical access lines 703-1A, 703-1B (e.g., corresponding to conductive materials 640, previously mentioned) is illustrated by a dashed line indicating a location set in from the plane and orientation of the drawing sheet.

FIG. 7C illustrates a cross sectional view, taken along cut-line B-B′ in FIG. 7A. FIG. 7C shows another view of the semiconductor structure at a particular point in one example of semiconductor device fabrication process.

In the example of FIG. 7C, the semiconductor device fabrication process comprises using additional a photolithographic processes to pattern one or more photolithographic masks (e.g., 735, 536, and/or 637) to form complementary, horizontally oriented digit lines for a two access device, one storage node memory. One or more etchant processes can be utilized to form a vertical openings 771. The vertical openings 771 may be formed concurrently or sequentially. The one or more etchant processes forms vertical openings 771 to expose third sidewalls in the repeating iterations of alternating layers of a first dielectric material, 730-1, 730-2, . . . , 730-N, a semiconductor material, 732-1, 732-2, . . . , 732-N, and a second dielectric material, 733-1, 733-2, . . . , 733-N, in the vertical stack. In some embodiments, the vertical opening 771 and vertical opening 728 may also be utilized for transistor formation (e.g., in regions of an elongated vertical, pillar column 742). The one or more etchant processes may comprise an anisotropic etching process.

FIG. 7D is a cross-sectional view, at one stage of a semiconductor device fabrication process in accordance with a number of embodiments of the present disclosure. FIG. 7D shows another view of the semiconductor structure at a particular point in one example of semiconductor device fabrication process.

FIG. 7D illustrates the vertical opening 771 in the vertical stack 716 on a working surface of a semiconductor substrate 700 and including an insulator 720. The vertical opening 771 extends in the vertical direction 711. Multiple second vertical openings 771 may be formed through the layers of materials. The second vertical openings 771 may be formed to expose vertical sidewalls in the vertical stack 701. While FIG. 7D illustrates the vertical opening 771 through which source/drain region 721 (shown in FIG. 7E) and conductive material 777 (shown in FIG. 7F) are formed, analogous processes, as discussed herein, can be performed through vertical openings 771 (shown in FIG. 7B) to form another source/drain region (e.g., source/drain region 323 shown in FIG. 3) and another conductive material (e.g., complementary digit line 106-B, 206-B, 306-B respectively shown in FIGS. 1-3).

FIG. 7E is a cross-sectional view, at one stage of a semiconductor device fabrication process in accordance with a number of embodiments of the present disclosure. FIG. 7E shows another view of the semiconductor structure at a particular point in one example of semiconductor device fabrication process.

As shown in FIG. 7E, a selective etchant process may etch the second dielectric material 733 to form a horizontal opening 773. The selective etchant process may be performed such that the horizontal opening 773 has a length or depth (e.g., a distance (DIST 2) 776 from the second vertical opening 771. The distance (DIST 2) 776 may be controlled by controlling time, composition of etchant gas, and etch rate of a reactant gas flowed into the second vertical opening 771, e.g., rate, concentration, temperature, pressure, and time parameters. As such, the second dielectric material 733 may be etched a second distance (DIST 2) 776 from the second vertical opening 771 (e.g., from the sidewalls of the stack 716). The selective etch may be isotropic, but selective to the second dielectric material 733, substantially stopping on the first dielectric material 730 and the semiconductor material 732. Thus, in one example embodiment, the selective etchant process may remove substantially all of the second dielectric material 733 from a top surface of the semiconductor material 732 to a bottom surface of the first dielectric material 730 (e.g., oxide material) in a layer above while etching horizontally the distance (DIST 2) 776 from the second vertical opening 771 between the semiconductor material 732 and the first dielectric material 730. In this example the horizontal opening 773 will have a height (H1) 731 substantially equivalent to and be controlled by a thickness, to which the second dielectric layer 733 (e.g., nitride material) was deposited. Embodiments, however, are not limited to this example. As described herein, the selective etchant process may etch the second dielectric material 733 to a second distance (DIST 2) 776 and to a height (H1) 731.

Selective etchant process utilized herein may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O₂) or O₂ and sulfur dioxide (SO₂) (O₂/SO₂) may be utilized. A dry etch chemistries of O₂ or of O₂ and nitrogen (N₂) (O₂/N₂) may be used. Alternatively, or in addition, a selective etch may comprise a selective etch chemistry of phosphoric acid (H₃PO₄) or hydrogen fluoride (HF) and/or dissolving a material (e.g., a portion of dielectric material 733) using a selective solvent, for example NH₄OH or HF, among other possible etch chemistries or solvents. As an example, the etchant process may cause an oxidization of only the dielectric material 733 (e.g., a nitride material). As shown in the example of FIG. 7E, the etchant process may form a protective oxide coating, e.g., second oxide material 745, on the semiconductor material 732. Hence, the first dielectric material 730 and the semiconductor material 732 may be left intact during a selective etchant process. For example, a selective etchant process may etch a portion of the dielectric material 733 (e.g., a nitride material), while not removing the dielectric material 730 (e.g., an oxide material) or the semiconductor material 732.

As noted, the semiconductor material 732 may be protected by a oxide material 745 formed on the semiconductor material 732 during a selective etchant process. The oxide material 745 may be present on all iterations of the semiconductor material 732. For example, the oxide material 745 may be present on a sidewall to the first semiconductor material 732-1, the second semiconductor material 732-2, and the third semiconductor material 732-3, etc., in the vertical opening 771 (as will as vertical opening 728) within the stack 716.

While not shown in FIG. 7E, a number of embodiments provide that the second dielectric material 733 can be selectively horizontally etched a distance greater than the distance (DIST 2) 776 from the second vertical opening 771. Selectively etching the second dielectric material 733 the distance greater than the distance (DIST 2) 776 can provide access to a region of semiconductor material 732 to be gas phased doped for the formation of a shared source/drain region, such as shared source/drain region 323 shown in FIG. 3. Referring again to FIG. 3, the shared source/drain region 323 is located between the source/drain region 321 and the source/drain region 324 in the horizonal direction (D2) 305. After the region of semiconductor material 732 has gas phased doped for the formation of the shared source/drain region (e.g., shared source/drain region 323), additional second dielectric material 733 can be deposited (e.g., to the second vertical opening 771). Following the additional deposition of the additional second dielectric material 733, the second dielectric material 733 can be selectively horizontally etched the distance (DIST 2) 776, as previously discussed. Alternatively, the shared source/drain region 323 may be formed by deposition of select materials during formation of the vertical stack (e.g., vertical stack 416 shown in FIG. 4).

A number of embodiments provide that the source/drain regions 321, 323 may be formed by gas phase doping a dopant into a top surface portion of the semiconductor material 732 via horizontal openings via the vertical openings 771 and/or 728. Gas phase doping may be used to achieve a highly isotropic e.g., non-directional doping. In another example, thermal annealing with doping gas, such as phosphorous may be used with a high energy plasma assist to break the bonding. Embodiments are not so limited and other suitable semiconductor fabrication techniques may be utilized. The source/drain regions discussed herein may be formed by gas phase doping phosphorus (P) atoms, as impurity dopants, at a high plasma energy such as PECVD to form a high concentration, n-type doped (n+) region in the top surface of the semiconductor material 732, for example.

FIG. 7F is a cross-sectional view, at one stage of a semiconductor device fabrication process in accordance with a number of embodiments of the present disclosure. FIG. 7F shows another view of the semiconductor structure at a particular point in one example of semiconductor device fabrication process.

As show in FIG. 7F, a source/drain region 721 may be formed by gas phase doping a top region of the semiconductor material 732. Further, as shown in FIG. 7F, a conductive material 777 may be deposited into a portion of the second vertical opening 771 (e.g., using a chemical vapor deposition (CVD) process) such that the conductive material 777 may also be deposited into the horizontal opening 773 (shown in FIG. 7D). The conductive material 777 may be formed to be in contact with source/drain region 721. In some embodiments, the conductive material 777 may comprise a titanium nitride (TiN) material. In some embodiments the conductive material 777 may be tungsten (W). In this example, some embodiments may include forming the tungsten (W) material according to a method as described U.S. patent application Ser. No. 16/943,108, entitled “Digit Line Formation for Horizontally Oriented Access Devices. The conductive material 777 may form a laterally (e.g., horizontally) oriented digit line (e.g., 107, 207, 307 shown in FIGS. 1-3). As shown in FIG. 7F, an oxide material 745 may be utilized to protect sidewalls of the semiconductor material 7321 in second vertical opening 771.

FIG. 7G is a cross-sectional view, at one stage of a semiconductor device fabrication process in accordance with a number of embodiments of the present disclosure. FIG. 7G shows another view of the semiconductor structure at a particular point in one example of semiconductor device fabrication process.

As shown in FIG. 7G, the oxide material 745 is removed (e.g., selectively etched away). A portion of the source/drain region 721, and a first portion 778 of the semiconductor material beneath the source/drain region 721 may be selectively etched away to allow for formation of a body contact, in the vertical opening 771, to a body region of the horizontal transistor; alternatively, the vertical opening 771 may be filled with another material (e.g., a dielectric material). In this example, the conductive material 777, a portion of the source/drain region 721 and a top portion (e.g., first portion 778 of the semiconductor material 732 beneath the source/drain region 721) may also be etched back to a third distance (DIST 3) 783 from the second vertical opening 771. The etch may be performed using an etchant process, e.g., using an atomic layer etching (ALE) or other suitable technique. In some embodiments, the source/drain region 721 may be etched to the same horizontal distance (DIST 3) 783 from the second vertical opening 771 as the conductive material 777.

Thus, a horizontal opening 772 may be formed by the etching the portion of the source/drain region 721 and the top surface (e.g., 778) of the semiconductor material 732 beneath the source/drain region 721 the third horizontal distance (DIST 3) 783 from the second vertical opening 771. As such, the horizontal openings 772 may have a vertical height (H2) 785. The vertical height (H2) 785 may be greater (e.g., taller vertically) than a combination of the height (H1) 731 of the horizontal opening 773 formed in the second dielectric material (e.g., nitride material) and the height (e.g., depth of gas phase doping into the top surface of the semiconductor material 732), of the source/drain region 721. For example, the vertical height (H2) 785 may also include a height of the top portion (e.g., 778) of the semiconductor material 732 that was etched away. Thus, the distance (DIST 3) 783 may be shorter than the distance (DIST 2) 776, but the vertical height (H2) 785 may be taller than the height (shown as H1 in FIG. 7D).

FIG. 7H is a cross-sectional view, at one stage of a semiconductor device fabrication process in accordance with a number of embodiments of the present disclosure. FIG. 7H shows another view of the semiconductor structure at a particular point in one example of semiconductor device fabrication process.

As shown in FIG. 7H, a dielectric material 774 may be deposited into the second vertical opening 771. The dielectric material 774 may fill the vertical opening 771; or, the dielectric material may be recessed back (as shown in FIG. 7G) to remove the dielectric material 774 from the second vertical opening 771 and maintain the second vertical opening 771 to allow for deposition of a conductive material (e.g., 295 shown in FIG. 2; not shown in FIG. 7H) to form a direct, electrical contact between such conductive material deposited within the second vertical opening 771 and a second portion 779 of the semiconductor material 732 (e.g., body region contact) of the horizontally oriented transistor (e.g., 215-A in FIG. 2) within the vertical stack 716. In some embodiments, the dielectric material 774 may be etched away from the second vertical opening 771 to expose the sidewalls of the first dielectric material 730, the dielectric material 774, and a second portion 779 of the semiconductor material 732.

FIGS. 8A-8B are views illustrating portions of a semiconductor device in accordance with a number of embodiments of the present disclosure. FIG. 8A illustrates a cell array of a 3D semiconductor memory device according to an embodiment of the present disclosure having vertically oriented gates (e.g., vertically oriented WLs 803-A and 803-B) oriented in the third direction (D3) 811 and horizontally oriented digit lines (e.g., Dl 806-1A and DL* 806-1B) oriented in the first direction (D1) 809. FIG. 8B illustrates a cell array of a 3D semiconductor memory device according to an embodiment of the present disclosure having vertically oriented digit lines (e.g., Dl 806-A and DL* 806-B) oriented in the third direction (D3) 811 and horizontally oriented gates (e.g., horizontally oriented WLs 803-1A and 803-1B) oriented in the first direction (D1) 809. For ease of illustration, the description which follows will accord to the embodiment of FIG. 8A. However, embodiments are not so limited, and a rotation of the gate and digit line configuration and architecture shown in FIG. 8A by ninety (90) degrees relative to the third direction (D3) 811 will produce the configuration and architecture illustrated in FIG. 8B which is equally covered with the embodiments described herein.

FIG. 8A illustrates the vertically oriented stack of memory cells may be fabricated such that the memory cells are formed on plurality of vertical levels (e.g., a first level 813-1 (L1), a second level 813-2 (L2), and a third level 813-3 (L3)). The repeating, vertical levels, L1, L2, and L3, may be arranged (e.g., “stacked”), the vertical direction (D3) 811, and may be separated from the substrate by an insulator material, as described in FIGS. 4-7. Each of the repeating, vertical levels, L1, L2, and L3 may include a number of components, e.g., regions, to the horizontally oriented transistors 815 A, 815-B, including vertically oriented gate pairs 803-A and 803-B that may connected together, e.g., “shorted” by a control line (or “access line” (AL) shown as 102 in FIG. 1A), and horizontally oriented, complementary digit line pairs, e.g., digit lines (DLs) 806-A and digit lines “bar” (DLs*) 806-B, each coupled respectively to first source/drain regions 821-A of the two (2) access devices, e.g., transitors 815-A and 815-B. The number of components to the horizontally oriented transistors 815-A and 815-B may be formed in a plurality of iterations of vertically, repeating layers within each level (e.g., as described in connection with FIGS. 4-7) and may extend horizontally in the second direction (D2) 805, analogous to second direction (D2) 105 shown in FIG. 1A.

In one example, the two transistors 815-A and 815-B are horizontally oriented and each share a horizontally oriented storage node 801 located between the two (2) horizontally oriented transistors 815-A and 815-B within a same plane, tier, or “level”, e.g., (L3), of the vertical 3D memory. The horizontally oriented transistors 815-A and 815-B are integrated with vertically oriented gates 803-A and 803-B and integrated with horizontally oriented, complementary digit lines, 806-A (DL) and 806-B (DL*), respectively coupled to sense amplifiers as shown in FIG. 1A. In various embodiments, the storage nodes may have a first electrode 861 coupled to the second source/drain region 823-A of a first access device 815-A and a second electrode 856 coupled to a second source/drain region 823-B of a second access device 815-B. The first and the second electrodes, 861 and 856, are thus floating and may be separated by a dielectric material 863, e.g., “high-k” dielectric material as the same has been described herein. In some embodiments the horizontally oriented, shared storage nodes 801 are capacitors. In some embodiments the horizontally oriented, shared storage nodes 801 are ferroelectric storage nodes. Embodiments are not limited to the capacitor storage node example given herein.

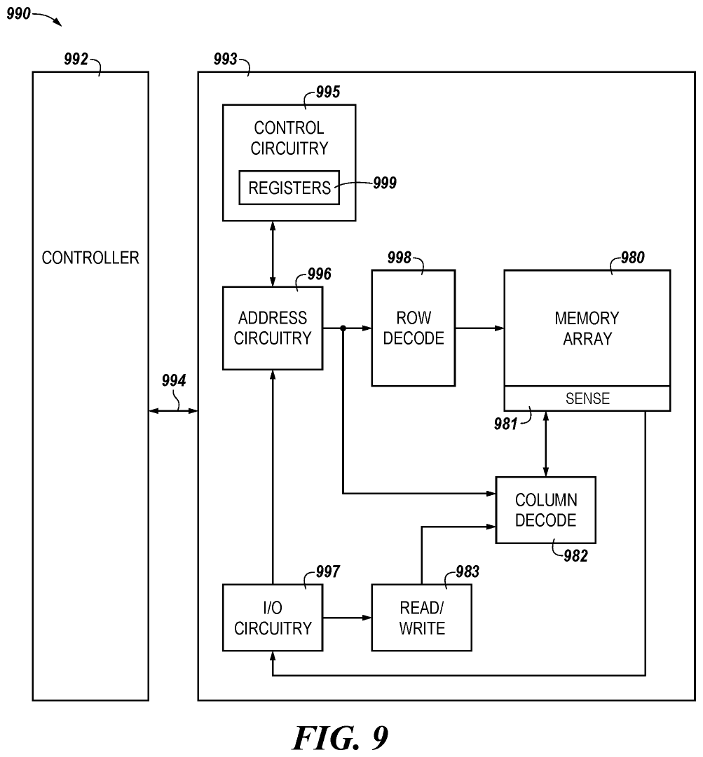

FIG. 9 is a block diagram of an apparatus in the form of a computing system including a memory device, in accordance with a number of embodiments of the present disclosure. FIG. 9 is a block diagram of an apparatus in the form of a computing system 990 including a memory device 993 in accordance with a number of embodiments of the present disclosure. As used herein, a memory device 993, a memory array 980, and/or a host 992, for example, might also be separately considered an “apparatus.” According to embodiments, the memory device 993 may comprise at least one memory array 980 with a memory cell formed having horizontally oriented access devices, sharing one horizontally oriented storage node. For example, as described in FIG. 8, the horizontally oriented access devices each share a horizontally oriented storage node located between the two (2) horizontally oriented transistors within a same plane, tier, or “level”, e.g., (L3), of the vertical 3D memory. The horizontally oriented transistors are integrated with vertically oriented gates and integrated with horizontally oriented, complementary digit lines, respectively coupled to sense amplifiers as shown in FIG. 1A.

In this example, system 990 includes a host 992 coupled to memory device 993 via an interface 994. The computing system 990 can be a personal laptop computer, a desktop computer, a digital camera, a mobile telephone, a memory card reader, or an Internet-of-Things (IOT) enabled device, among various other types of systems. Host 992 can include a number of processing resources (e.g., one or more processors, microprocessors, or some other type of controlling circuitry) capable of accessing the memory device 993. The system 990 can include separate integrated circuits, or both the host 992 and the memory device 993 can be on the same integrated circuit. For example, the host 992 may be a system controller of a memory system comprising multiple memory devices 993, with the control circuitry 995 providing access to the respective memory devices 993 by another processing resource such as a central processing unit (CPU).

In the example shown in FIG. 9, the host 992 is responsible for executing an operating system (OS) and/or various applications (e.g., processes) that can be loaded thereto (e.g., from memory device 993 via control circuitry 995). The OS and/or various applications can be loaded from the memory device 993 by providing access commands from the host 992 to the memory device 993 to access the data comprising the OS and/or the various applications. The host 992 can also access data utilized by the OS and/or various applications by providing access commands to the memory device 993 to retrieve said data utilized in the execution of the OS and/or the various applications.

For clarity, the system 990 has been simplified to focus on features with particular relevance to the present disclosure. The memory array 980 can be an array having memory cells according to the embodiments described herein. Although a single array 980 is shown in FIG. 9, embodiments are not so limited. For instance, memory device 993 may include a number of arrays 980 (e.g., a number of banks of DRAM cells).

The memory device 993 includes address circuitry 996 to latch address signals provided over the interface 994. The interface can include, for example, a physical interface employing a suitable protocol (e.g., a data bus, an address bus, and a command bus, or a combined data/address/command bus). Such protocol may be custom or proprietary, or the interface 994 may employ a standardized protocol, such as Peripheral Component Interconnect Express (PCIe), Gen-Z, CCIX, or the like. Address signals are received and decoded by a row decoder 998 and a column decoder 982 to access the memory array 980. Data can be read from memory array 980 by sensing voltage and/or current changes on the sense lines using sensing circuitry 981. The sensing circuitry 981 can comprise, for example, sense amplifiers that can read and latch a page (e.g., row) of data from the memory array 980. The I/O circuitry 997 can be used for bi-directional data communication with the host 992 over the interface 994. The read/write circuitry 983 is used to write data to the memory array 980 or read data from the memory array 980. As an example, the circuitry 983 can comprise various drivers, latch circuitry, etc.

Control circuitry 995 includes registers 999 and decodes signals provided by the host 992. The signals can be commands provided by the host 992. These signals can include chip enable signals, write enable signals, and address latch signals that are used to control operations performed on the memory array 980, including data read operations, data write operations, and data erase operations. In various embodiments, the control circuitry 995 is responsible for executing instructions from the host 992. The control circuitry 995 can comprise a state machine, a sequencer, and/or some other type of control circuitry, which may be implemented in the form of hardware, firmware, or software, or any combination of the three. In some examples, the host 992 can be a controller external to the memory device 993. For example, the host 992 can be a memory controller which is coupled to a processing resource of a computing device.

FIG. 10 illustrates an embodiment of operation for a two access device, one storage node memory cell, e.g., (2T1C), in contrast to a one access device, one storage node memory cell, e.g., (1T1C). In FIG. 10, “Write and Retention” are contrasted according to this example embodiment operation for a two transistor, shared floating capacitor (e.g., ₂T₁C) memory cell relative to one transistor, one capacitor (1T1C) memory cells.

As noted above in connection with FIG. 1A, memory cells may be written to, or read from, using the vertically oriented gates 103-1A, 103-1B, 103-2A, 103-2B . . . , 103-QA, 103-QB (e.g., wordlines (WL/WLB)), and the complementary pairs of digit lines, 106-1A and 106-1B, 106-2A and 106-2B, . . . 106-PA and 106-PB (e.g., DL and DL*, or DL_bar). For example the vertically oriented gates 103-1A, 103-1B, 103-2A, 103-2B . . . , 103-QA, 103-QB (e.g., wordlines (WL/WLB)) can be activated, e.g., driven to a gate potential Vg of Vcc (power supply voltage (common collector)) pumped (Vccp), and the selected complement digit line (DL*) 106-1B, 106-2B, . . . , 106-PB can be driven to a voltage potential Vdd (power supply voltage (drain)), while digit line (DL) 106-1A, 106-2A, . . . , 106-PA is pulled to a ground potential (e.g., Vdl=0). This will result in a high voltage potential being placed on one electrode of the storage node capacitor, e.g., on the second node, while a low voltage potential will be formed on the other electrode of the storage node capacitor, e.g., on the first electrode. When the gate voltage potential (Vg) is removed, e.g., “off”, and the selected complement digit line (DL*) 106-1B, 106-2B, . . . , 106-PB is returned to ground potential (e.g., VDL* or Vdl_bar=0) and the digit line (DL) 106-1A, 106-2A, . . . , 106-PA is returned to voltage potential Vdd (e.g., VDL =Vdd) a charge (or potential difference of Vcc) will be held across the first electrode and the second electrode on the on the storage node capacitor with good stored charge retention. In a read operation, the above “write” sequence may be reversed.

As used herein, the term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements. Unless stated otherwise, where a single element is discussed, it is understood that all similar elements are referred to.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” an other element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A memory device, comprising:
a first horizontally oriented access device having a first source/drain region and a second source/drain region separated by a first channel region, the first access device being operatively controlled by a first gate; and
a second horizontally oriented access device having a first source/drain region and a second source/drain region separated by a second channel region, the second access device being operatively controlled by a second gate; and
a shared storage node coupled between the second source/drain regions of the first access device and the second access device.

2. The memory device of claim 1, wherein the first and the second gates are electrically connected.

3. The memory device of claim 1, wherein the first and the second gates are vertically oriented gates.

4. The memory device of claim 3, wherein the first source/drain region of the first horizontally oriented access device and the first source/drain region of the second horizontally oriented access device are coupled to a complimentary pair of horizontally oriented digit lines electrically connected to a sense amplifier.

5. The memory device of claim 1, wherein the first and the second gates are horizontally oriented gates.

6. The memory device of claim 5, wherein the first source/drain region of the first horizontally oriented access device and the first source/drain region of the second horizontally oriented access device are coupled to a complimentary pair of vertically oriented digit lines electrically connected to a sense amplifier.

7. The memory device of claim 1, wherein the shared storage node comprises a first electrode coupled to the second source/drain region of the first access device and a second electrode coupled to the second source/drain region of the second access device.

8. The memory device of claim 1, wherein the first and the second access devices are thin film transistors (TFTs) and the shared storage node is a horizontally oriented capacitor.

9. The memory device of claim 1, wherein the first and the second access devices are thin film transistors (TFTs) and the shared storage node is a ferroelectric storage node.

10. The memory device of claim 1, wherein the memory device comprises a vertically oriented three-dimensional (3D), multi-tiered memory array with each tier having two transistor, one capacitor (2T1C) memory cells.

11. A memory device, comprising:
a first horizontally oriented access device having a first source/drain region and a second source/drain region separated by a first channel region, the first access device being operatively controlled by a first gate; and
a second horizontally oriented access device having a first source/drain region and a second source/drain region separated by a second channel region, the second access device also being operatively controlled by a second gate; and
a storage node comprising:
a first electrode coupled to the second source/drain region of the first access device; and
a second electrode coupled to the second source/drain region of the second access device.

12. The memory device of claim 11, wherein the first and the second gates are gate on two side (G2S) structures on opposing sides, respectively, of the first and the second channel regions.

13. The memory device of claim 11, wherein the first gate and the second gate are electrically coupled together.

14. The memory device of claim 11, wherein the first and the second horizontally oriented access devices are thin film transistors (TFTs) and the shared storage node is a horizontally oriented capacitor located in a same horizontal tier to form a two transistor, one capacitor (2T1C) memory cell.

15. The memory device of claim 14, wherein the memory device comprises a vertically oriented three-dimensional (3D), multi-tiered memory array with each tier having two transistor, one capacitor (2T1C) memory cells.

16. The memory device of claim 11, wherein the first source/drain region of the first horizontally oriented access device and the first source/drain region of the second horizontally oriented access device are coupled to a complimentary pair of horizontally oriented digit lines electrically connected to a sense amplifier.

17. The memory device of claim 11, wherein the storage node is a shared storage node located in a same plane, horizontally between the first access device and the second access device.

18. The memory device of claim 17, wherein the shared storage node is a capacitor and both electrodes of the capacitor are floating electrodes.

19. The memory device of claim 11, wherein the storage node is a horizontally oriented, ferroelectric storage node located between the first access device and the second access device.

20. A memory device, comprising:
an array of vertically stacked two transistor, one capacitor (2T1C) memory cells, the 2T1C memory cells, comprising:
a first horizontally oriented transistor having a first source/drain region and a second source/drain region separated by a first channel, the first horizontally oriented transistor being operatively controlled by a first vertically oriented gate;
a second horizontally oriented transistor having a first source/drain region and a second source/drain region separated by a second channel, the second horizontally oriented transistor being operatively controlled by a second vertically oriented gate; and
a floating capacitor coupled to the second source drain regions of the first and the second horizontally oriented transistors;
a first horizontally oriented digit line coupled to the first source/drain region of the first horizontally oriented transistor; and
a second horizontally oriented digit line coupled to the first source/drain region of the second horizontally oriented transistor.

21. The memory device of claim 20, wherein the first and the second horizontally oriented digit lines are complementary digit lines coupled to a sense amplifier.

22. The memory device of claim 20, wherein the floating capacitor comprises:
a first electrode coupled to the second source/drain region of the first horizontally oriented transistor; and
a second electrode coupled to the second source/drain region of the second horizontally oriented transistor.

23. The memory device of claim 20, wherein the first and the second horizontally oriented transistors are thin film transistors (TFTs).

24. A method for operating vertical three-dimensional (3D) memory, comprising:
coupling a first source/drain region of a first horizontally oriented transistor to a first one of a complementary pair of horizontally oriented digit lines;
coupling a first source/drain region of a second horizontally oriented transistor to a second one of the complementary pair of horizontally oriented digit lines;
coupling a floating capacitor to the second source/drain regions of the first and the second horizontally oriented transistors; and
coupling the complementary pair of horizontally oriented digit lines to a sense amplifier.

25. The method of claim 24, wherein the method further comprises operatively controlling the first and the second horizontally oriented transistors with a first vertically oriented gate and a second vertically oriented gate, respectively.

26. The method of claim 25, wherein the method further comprises electrically connecting the first and the second vertically oriented gates.

27. A method of forming vertical three-dimensional (3D) memory, comprising:
forming a first horizontally oriented thin film transistor (TFT) in a first horizontal tier of a multi-tier 3D memory, the first TFT having a first source/drain region and a second source/drain region separated by a first channel region;
forming a second TFT in the first horizontal tier of the multi-tier 3D memory, the second TFT having a first source/drain region and a second source/drain region separated by a second channel region;
forming a first digit line for a complementary digit line pair coupled to the first source/drain region of the first TFT;
forming a second digit line of the complementary digit line pair coupled to the first source/drain region of the second TFT; and
forming a floating gate capacitor between the first that the second TFTs, the floating gate capacitor having a first electrode coupled to the second source/drain region of the first TFT and a second electrode coupled to the second source/drain region of the second TFT.

28. The method of claim 27, the method further comprising coupling the complementary pair of digit lines to a sense amplifier.

29. The method of claim 28, the method further comprising horizontally forming the complementary pair of digit lines.

30. The method of claim 27, the method further comprising:
forming a first vertically oriented gate opposing the first channel in the first TFT; and
forming a second vertically oriented gate opposing the second channel in the second TFT.

31. The method of claim 30, the method further comprising electrically connecting the first and the second vertically oriented gates.

32. The method of claim 30, the method further comprising:
forming a pair of first vertically oriented gates on opposite sides opposing the first channel in the first TFT to provide a gate on two side (G2S) structure; and
forming a pair of second vertically oriented gates on opposite sides opposing the second channel in the second TFT to provide a gate on two side (G2S) structure.

33. The method of claim 27, the method further comprising forming the first and the second channels as indium gallium zinc oxide (IGZO) material channels.
